(19) United States
(12) Patent Application Publication
(10) Pub. No.: US 2015/0263105 A1
(43) Pub. Date: Sep. 17, 2015

(54) NONVOLATILE SEMICONDUCTOR STORAGE DEVICE

(71) Applicant: KABUSHIKI KAISHA TOSHIBA, Minato-ku (JP)

(72) Inventors: Naoki KUSUNOKI, Isehara (JP); Shinya Naito, Yokkaichi (JP); Mitsutoshi Nakamura, Yokkaichi (JP)

(73) Assignee: KABUSHIKI KAISHA TOSHIBA, Minato-ku (JP)

(21) Appl. No.: 14/644,756

(22) Filed: Mar. 11, 2015

Related U.S. Application Data
(60) Provisional application No. 61/951,966, filed on Mar. 12, 2014.

(51) Int. Cl. H01L 29/36; H01L 29/10; G11C 16/26; H01L 29/788; H01L 29/423; H01L 29/792; H01L 29/51; H01L 27/115

(52) U.S. Cl. CPC H01L 29/365; H01L 29/518; H01L 29/1079; H01L 27/11524; H01L 27/11529; H01L 29/788; H01L 29/42328; H01L 27/1157; H01L 27/11573; H01L 29/792; H01L 29/42344; G11C 16/26

(57) ABSTRACT

A nonvolatile semiconductor storage device includes a plurality of memory cells arranged in a matrix in a memory cell region of a semiconductor substrate; a peripheral circuit disposed in a peripheral circuit region outside the memory cell region and configured to read data from and write data to the memory cells; and a word line transfer transistor provided in the peripheral circuit and having a gate electrode above the semiconductor substrate via a gate insulating film and two impurity diffusion regions provided in two sides of the gate electrode, the word line transfer transistor being configured to supply a voltage to a word line connecting the memory cells; wherein among the two impurity diffusion regions of the word line transfer transistor, a level of a surface position of the semiconductor substrate in one impurity diffusion region is lower than a level of a surface position of the semiconductor substrate in the other impurity diffusion region.

### CROSS-REFERENCE TO RELATED APPLICATION(S)

This application is based upon and claims the benefit of priority from U.S. Provisional Patent Application No. 61/951,966, filed on, Mar. 12, 2014 the entire contents of which are incorporated herein by reference.

### FIELD

Embodiments disclosed herein relate to a nonvolatile semiconductor storage device.

### BACKGROUND

In a NAND flash memory device which is one example of a nonvolatile semiconductor storage device, high programming voltage Vpgm is applied to the word line when programming data into the memory cell. Programming voltage Vpgm is applied by the word line transfer transistor in the peripheral circuit. However, it may not be possible to transfer the desired programming voltage Vpgm as the programming and erasing operations are repeated.

One possible reason for this may be explained as follows. When programming voltage Vpgm is applied between the gate electrode of word line transfer transistor and the electrode connected to the source/drain region, electrons are produced by impact ionization. The electrons are trapped in the silicon nitride film serving as a liner film formed so as to cover the gate electrodes, and the resistance of the diffusion layer is increased by the influence of the trapped charge.

Another possible reason may be explained by the presence of wiring (M0), for transferring the voltages to other word lines WL of the memory cell, provided above the source/drain region of word line transfer transistor. Because the voltage (Vpass) applied to wiring M0 is lower than programming voltage Vpgm, it causes a further increase in the resistance of the diffusion layer.

One possible approach for overcoming the above described problems may be reducing impact ionization by relaxing the electric field by increasing the distance between the gate electrode and the electrode connected to the source/drain diffusion layer for example. However, employing this approach creates another problem in which the area of the peripheral circuit is increased.

Further, in a conventional NAND flash memory device, a memory cell configuration was employed in which the upper surface and the side surfaces of the floating gate were covered by interelectrode insulating film. In contrast, a flat-type memory cell is being developed in which the portion corresponding to the floating gate electrode is not covered by interelectrode insulating film. In the flat-type memory cell, the thickness of the floating gate electrode is reduced in order to reduce the influence of the adjacent memory cell. Thus, in the select gates disposed at both ends of the NAND string, it is difficult to adopt a configuration in which the floating gate and the control gate are short circuited because of process constraints.

In such case, when the select gate electrode possesses a floating gate, this portion becomes electrically floated and thus, is affected by the potential from the contact disposed in the proximity of the select gate to thereby vary the threshold (Vth) of the select gate. Thus, when writing data to the memory cell, the select gate disposed in the unselected bit line is unable to maintain the turned off state by the variation in the threshold voltage and increases the leakage current.

### BRIEF DESCRIPTION OF THE DRAWINGS

FIG. 1 pertains to a first embodiment and is one example of an equivalent circuit of an electrical configuration of a semiconductor device.

FIG. 2A is one example of a plan view schematically illustrating a memory cell region.

FIG. 2B is one example of a plan view of a transistor in a peripheral circuit region.

FIG. 3A is one example of a vertical cross-sectional view taken along line 3A-3A of FIG. 2A.

FIG. 3B is one example of a vertical cross-sectional view taken along line 3B-3B of FIG. 2A.

FIG. 3C is one example of a vertical cross-sectional view taken along line 3C-3C of FIG. 2B.

FIG. 4 indicates the simulation model performed for the structure illustrated in FIG. 3C.

FIG. 5 indicates the simulation result (part 1)

FIG. 6 indicates the simulation result (part 2)

FIG. 7 indicates the simulation result (part 3)

FIG. 8 illustrates one example of a vertical cross-sectional side surface view taken along line 3C-3C in FIG. 2B illustrating one phase of the manufacturing process flow (part 1).

FIG. 9 illustrates one example of a vertical cross-sectional side surface view taken along line 3C-3C in FIG. 2B illustrating one phase of the manufacturing process flow (part 2).

FIG. 10 illustrates one example of a vertical cross-sectional side surface view taken along line 3C-3C in FIG. 2B illustrating one phase of the manufacturing process flow (part 3).

FIG. 11 pertains to a second embodiment and illustrates one example of a vertical cross-sectional side surface view taken along line 3C-3C in the FIG. 2B.

FIG. 12 illustrates one example of a vertical cross-sectional side surface view taken along line 3C-3C in FIG. 2B illustrating one phase of the manufacturing process flow (part 1).

FIG. 13 illustrates one example of a vertical cross-sectional side surface view taken along line 3C-3C in FIG. 2B illustrating one phase of the manufacturing process flow (part 2).

FIG. 14 illustrates one example of a vertical cross-sectional side surface view taken along line 3C-3C in FIG. 2B illustrating one phase of the manufacturing process flow (part 3).

FIG. 15A pertains to a third embodiment and illustrates one example of a vertical cross-sectional side surface view taken along line 15A-15A in the FIG. 2A.

FIG. 15B is one example of a vertical cross sectional view taken along line 3B-3B of FIG. 2A.

FIG. 16A is a chart for describing the operation (Part 1)

FIG. 16B is a chart for describing the operation (Part 2).

FIG. 17 is a chart for indicating a simulation result.

FIG. 18 illustrates one example of a vertical cross-sectional side surface view taken along line 15A-15A in FIG. 2A illustrating one phase of the manufacturing process flow (part 1).

FIG. 19 illustrates one example of a vertical cross-sectional side surface view taken along line 15A-15A in FIG. 2A illustrating one phase of the manufacturing process flow (part 2).

FIG. 20 illustrates one example of a vertical cross-sectional side surface view taken along line 15A-15A in FIG. 2A illustrating one phase of the manufacturing process flow (part 3).

FIG. 21 illustrates one example of a vertical cross-sectional side surface view taken along line 15A-15A in FIG. 2A illustrating one phase of the manufacturing process flow (part 4).

FIG. 22 pertains to a fourth embodiment and illustrates one example of a vertical cross-sectional side surface view taken along line 15A-15A in the FIG. 2A.

FIG. 23 illustrates one example of a vertical cross-sectional side surface view taken along line 15A-15A in FIG. 2A illustrating one phase of the manufacturing process flow (part 1).

FIG. 24 illustrates one example of a vertical cross-sectional side surface view taken along line 15A-15A in FIG. 2A illustrating one phase of the manufacturing process flow (part 2).

### DESCRIPTION

In one embodiment, a nonvolatile semiconductor storage device includes a plurality of memory cells arranged in a matrix in a memory cell region of a semiconductor substrate; a peripheral circuit disposed in a peripheral circuit region outside the memory cell region and configured to read data from and write data to the memory cells; and a word line transfer transistor provided in the peripheral circuit and having a gate electrode above the semiconductor substrate via a gate insulating film and two impurity diffusion regions provided in two sides of the gate electrode, the word line transfer transistor being configured to supply a voltage to a word line connecting the memory cells; wherein among the two impurity diffusion regions of the word line transfer transistor, a level of a surface position of the semiconductor substrate in one impurity diffusion region is lower than a level of a surface position of the semiconductor substrate in the other impurity diffusion region.

### First Embodiment

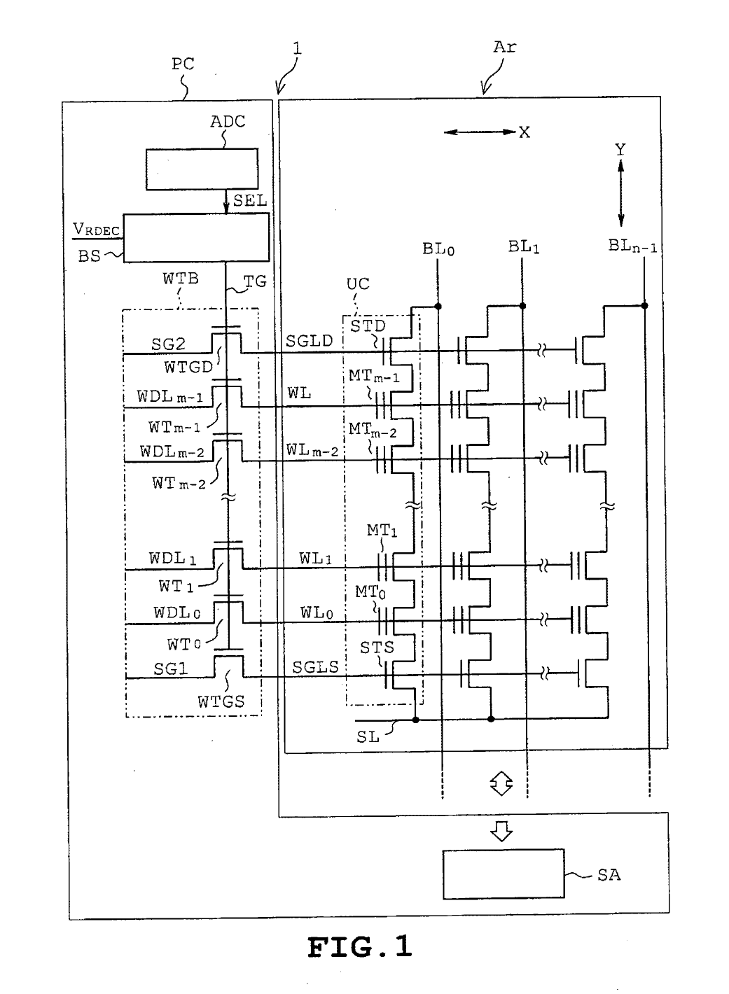

A first embodiment is described hereinafter through a NAND flash memory device application with references to FIGS. 1 to 10. The drawings are schematic and are not necessarily consistent with the actual measurements of the features such as the correlation of thickness to planar dimensions and the ratio of thicknesses of different layers. Further, directional terms such as up, down, left, and right are used in a relative context with an assumption that the worked surface, on which circuitry is formed of the later described semiconductor substrate faces up. Thus, the directional terms do not necessarily correspond to the directions based on gravitational acceleration.

FIG. 1 is one schematic example of a diagram illustrating an electrical configuration of a NAND flash memory device. As shown in FIG. 1, NAND flash memory device 1 is provided with memory cell array Ar, peripheral circuit region PC and input/output interface circuitry not shown. Memory cell array Ar is configured by multiplicity of memory cells arranged in a matrix. Peripheral circuit PC is configured to read/write/erase each of the memory cells in memory cell array Ar.

Memory cell array Ar includes multiplicity of cell units UC. Cell unit UC has 2^{k} number (for example 32(=m)) of series connected memory cell transistors MT₀ . . . MTₘ₋₁ situated between a couple of select gate transistors STD and STS. Select gate transistors STD are connected to bit line BL₀ . . . BLₙ₋₁, whereas Select gate transistors STS are connected to source line SL. Dummy cells may be series connected between the two Select gate transistors Trs1 and Trs2 in addition to 2^{k} number of memory cell transistors Trm. Gate electrodes MG of memory cell transistors Trm located in cell units UC aligned in the X direction are electrically connected by word line WL.

A block includes n number of cell units UC aligned in the X direction (row direction: the left and right direction as viewed in FIG. 1). The X direction is also referred to as a first direction. Memory cell array Ar includes multiple blocks aligned in the Y direction (column direction: the up and down direction in FIG. 1). The Y direction is also referred to as a second direction. FIG. 1 only shows one block for simplicity.

The memory cell region is surrounded by the peripheral circuit region and peripheral circuit PC is located in the periphery of memory cell array Ar. Peripheral circuit PC includes address decoder ADC, sense amplifier SA, booster circuit BS provided with a charge pump circuit, and transfer transistor WTB. Address decoder ADC is electrically connected to transfer transistor WTB through booster circuit BS.

Address decoder ADC selects a given block based on an incoming address signal provided from an external component and sends block selection signal SEL to step-up circuit BS. Booster circuit BS, when given a selection signal SEL of block B, steps up drive voltage V_{RDEC} received from a component outside address decoder ADC and supplies the stepped up drive voltage V_{RDEC}, being stepped up to a predetermined level, to each of transfer transistors WTGD, WTGS, and WT₀ to WTₘ₋₁ by way of transfer gate line TG.

Transfer transistor WTB is provided with transfer gate transistors WTGD being associated with Select gate transistors STD, transfer gate transistors WTGS being associated with Select gate transistors STS, word line transfer transistors WT₀ to WTₘ₋₁, being associated with each of memory cell transistors MT₀ to MTₘ₋₁, and the like. Transfer transistor WTB is given in each block B.

Transfer gate transistor WTGD is configured such that either of the drain and source is connected to select gate driver line SG2, and the remaining other is connected to select gate line SGLD. Transfer gate transistor WTGS is configured such that either of the drain and source is connected to select gate driver line SG1, and the remaining other is connected to select gate line SGLS. Each of word line transfer gate transistors WT₀ to WTₘ₋₁ is configured such that either of the drain and source is uniquely connected to word line drive signal lines WDL₀ to WDLₘ₋₁ respectively, and the remaining other is uniquely connected to word lines WL₀ to WLₘ₋₁ provided in memory cell array Ar (memory cell region M).

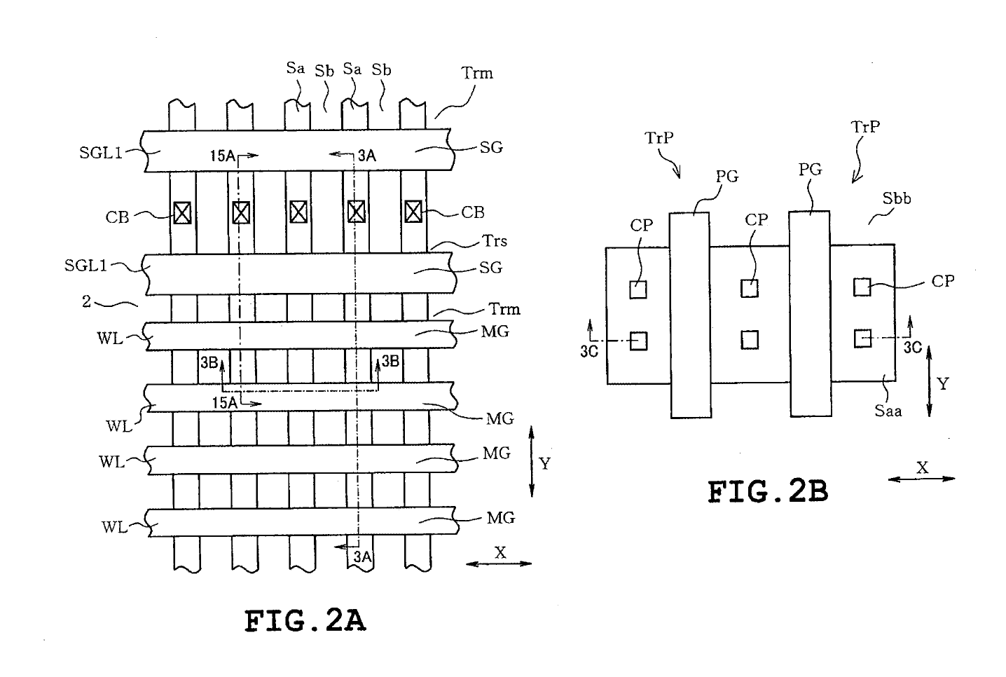

Gate electrodes SG of Select gate transistors STD of cell units UC aligned in the X direction are electrically connected by common select gate line SGLD. Similarly, gate electrodes SG of Select gate transistors STS of the cell units UC aligned in the X direction are electrically connected by common select gate line SGLS. The sources of Select gate transistors STS are connected to common source line SL. Select gate transistors STD and STS are each referred to as select gate transistor Trs in the descriptions for FIG. 2 and beyond.

Gate electrodes MG of memory cell transistors MT₀ to MTₘ₋₁, of the cell units UC aligned in the X direction are electrically connected by common word lines WL₀ to WLₘ₋₁ respectively. Memory cell transistors MT₀ to MTₘ₋₁ are each referred to as memory cell transistor Trm in the descriptions for FIG. 2 and beyond.

Gate electrodes of transfer transistors WTGD, WTGS, and WT₀ to WTₘ₋₁ are interconnected by common transfer gate line TG, which is turn, connected to an output terminal of booster circuit BS for supplying stepped up voltage. Sense amplifier SA is connected to bit lines BL₀ to BLₙ₋₁ and a latch circuit configured to temporarily store the data which has been read during data readout. Word line transfer transistor WT₀ to WTₙ₋₁ are each referred to as word line transfer transistor Trp in the descriptions for FIG. 2 and beyond.

FIG. 2A is one schematic example of a plan view illustrating a planar layout of memory cell region in part. As illustrated in FIG. 2A, element isolation regions Sb run in the Y direction, as viewed in FIG. 2A, of the memory cell region of a p-type silicon substrate 2. Silicon substrate 2 is one example of a semiconductor substrate. Element isolation region Sb takes an STI (shallow trench isolation) structure in which element isolation trenches are filled with an insulating film.

Multiple element isolation regions Sb are formed so as to be spaced from one another in the X direction as viewed in FIG. 2A by a predetermined distance. Thus element regions Sa, formed in a surface layer portion of semiconductor substrate 2 along the Y direction as viewed in FIG. 2A, are isolated in the X direction. In other words, element isolation region Sb is located between element regions Sa, meaning that the semiconductor substrate, is delineated into element regions Sa by element isolation region Sb.

Word lines WL extend in the X direction orthogonal to element regions Sa (the X direction as viewed in FIG. 2). Word lines WL are spaced from one another in the Y direction as viewed in FIG. 2A by a predetermined distance. In element region Sa located at the intersection with word line WL, gate electrode MG of memory cell transistor Trm is disposed.

The Y-direction adjacent memory cell transistors Trm form a part of a NAND string (memory cell string). Select gate transistors Trs are disposed Y-direction adjacent to the outer sides of memory cell transistors Trm located at both end portions of the NAND string. Select gate transistors Trs are aligned in the X direction and select gate electrodes SG of select gate transistors Trs are electrically interconnected by select gate line SGL1. Select gate electrode SG of select-gate transistor STS is formed in element region Sa intersecting with control line SGL1/SGL2. Bit line contact CB is formed in element region Sa located between adjacent gate electrodes SG.

FIG. 2B illustrates the layout of word line transfer transistor TrP located in the peripheral circuit. In semiconductor substrate 2 of FIG. 2B, element isolation region Sbb is formed so as to leave a rectangular element region Saa. The X direction and the Y direction represented in FIGS. 2A and 2B are related to the directions indicated in the cross-sectional views. Word line transfer transistor TrP, however, may be disposed in directions different from and thus not limited to those indicated in the drawings.

Two word line transfer transistors TrP, forming a pair, is formed in the rectangular element region Saa. Two isolated gate electrodes PG are formed so as to extend across element region Saa. Source/drain regions are formed by impurity diffusion in the three surface regions of element region Saa divided by the two gate electrodes PG. Two contact plugs CP establishing electric contact with silicon substrate 2 are formed in each of the source/drain regions.

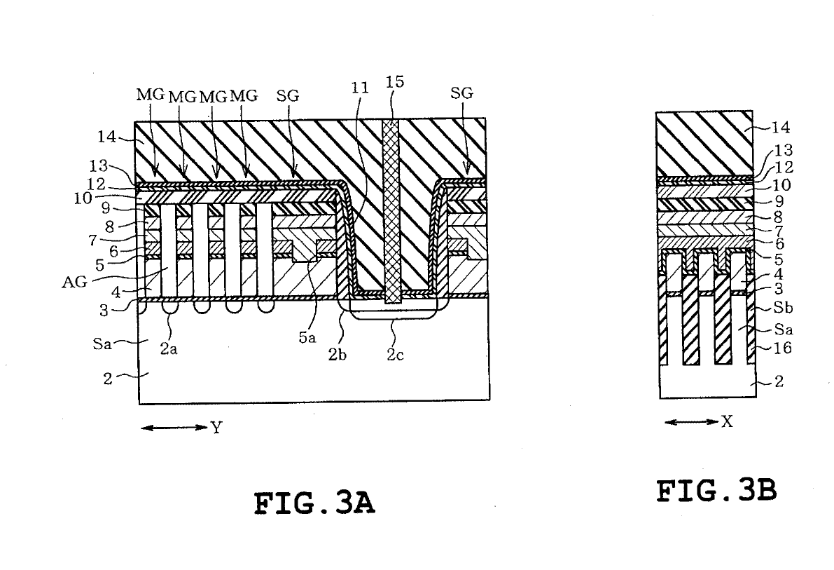

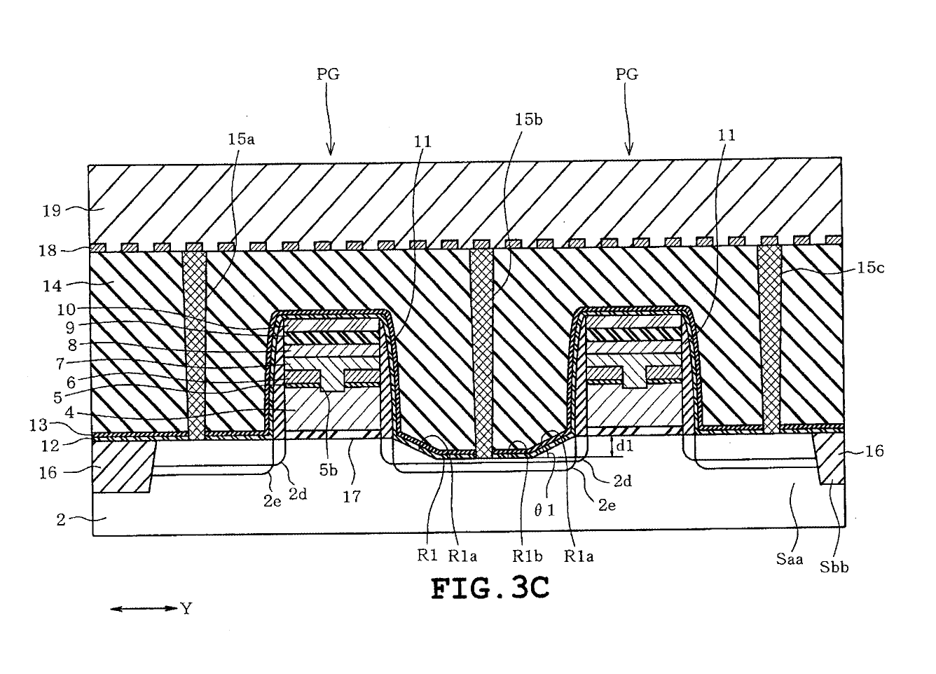

FIGS. 3A to 3C each schematically illustrates the cross-sectional structure of the elements in the memory cell region and the peripheral circuit region. FIG. 3A is a vertical cross sectional view taken along the Y direction of memory cell transistor Trm, select gate transistor Trs, and the region for forming bit line contact CB between select gate transistors Trs. FIG. 3B is a cross-sectional view taken along the X direction in which word line WL of memory cell transistors Trm are formed. FIG. 3C is a vertical cross-sectional view of word line transfer transistor TrP of peripheral circuit.

Next, a description will be given on the structures of memory cell transistors Trm and select gate transistors Trs of the memory cell region with reference to FIGS. 3A and 3B. Tunnel insulating film 3, serving as a first insulating film, is formed above the upper surface of silicon substrate 2. Gate electrodes MG of memory cell transistors Trm and gate electrodes SG of select transistors Trs are formed above the upper surface of tunnel insulating film 3. Memory cell transistor Trm comprises gate insulating film 3, gate electrode MG, and source/drain region 2a formed in silicon substrate 2 located on both sides of gate electrode MG. Multiple memory cell transistors Trm are formed so as to be adjacent in the Y direction. A pair of select gate transistors Trs are formed adjacent to memory cell transistors Trm located at end portions.

Gate electrode MG of memory cell transistor Trm is formed above tunnel insulating film 3 serving as a first insulating film such as a tunnel oxide film, and is provided with polycrystalline silicon film 4 serving as a first conductive layer, interelectrode insulating film 5 serving as a second insulating film, polycrystalline silicon films 6 and 7 serving as a second conductive layer, metal film 8 such as tungsten, and silicon nitride film 9. An ONO (oxide-nitride-oxide) film, NONON (nitride-oxide-nitride-oxide-nitride) film, or an insulating film having high-dielectric constant may be used as interelectrode insulating film 5.

Source/drain region 2a is provided in the surface layer portion of silicon substrate 2 located between gate electrodes MG and between gate electrodes SG and MG. LDD (Lightly Doped Drain) region 2b corresponding to the drain region is provided in the surface layer portion of silicon substrate 2 located between gate electrodes SG. Source/drain region 2a and LDD (Lightly Doped Drain) region 2b may be formed by doping impurities into the surface layer portion of silicon substrate 2. Drain region 2c is formed into the surface layer portion of silicon substrate 2 located between gate electrodes SG by introducing highly concentrated impurities to obtain an LDD structure.

Gate electrode SG of select transistor Trs is substantially identical in structure to gate electrode MG of memory cell transistor Trm. In gate electrodes SGS and SGD, an opening is formed through the interelectrode insulating film to short the floating gate electrode and the select gate electrode, and polycrystalline silicon film 4, interelectrode insulating film 5, polycrystalline silicon films 6 and 7, metal film 8, and silicon nitride film 9 are stacked above gate insulating film 3. Opening 5a is provided in the central portion of interelectrode insulating film 5 of gate electrode SG and polycrystalline silicon films 4 and 6 contacting one another are rendered electrically conductive.

Insulating film 10 for forming gaps is formed above the upper surfaces of silicon nitride films 9 located in the upper most portions of gate electrode MG and SG so as to extend across the upper surfaces of gate electrodes MG and SG. A silicon oxide film being formed under conditions providing poor gap fill capabilities may be used for example as insulating film 10. Air gaps (cavity) AG, providing insulation by not filling the gaps between gate electrodes MG and between gate electrode MG and SG, are provided by the formation of insulating film 10.

Air gaps AG are not provided in the portions where gate electrodes SG face one another. Spacers 11 are provided along the side surfaces of gate electrodes SG. A silicon oxide film may be used for example as spacer 11. Spacer 11 may be formed so as to extend from the upper surface portion of gate electrode SG and reach the upper surface of silicon substrate 2.

Silicon oxide film 12 and silicon nitride film 13 are formed one after another above insulating film 10 so as to cover the surface of insulating film 10, the surface of spacer 11 located between gate electrodes SG, and the surface of silicon substrate 2 exposed in the bottom surface portion. Interlayer insulating film 14 is formed above silicon nitride film 13 so as to fill the recesses between gate electrodes SG and cover the upper surfaces of gate electrodes MG and SG. Contact plug 15a extends through interlayer insulating film 14 from the upper portion to the lower portion thereof and further through silicon nitride film 13 and silicon oxide film 12 to reach silicon substrate 2 located in the recessed region between gate electrodes SG.

Referring to FIG. 3B illustrating the cross section taken along the X direction of memory cell transistors Trm, element regions Sa are isolated in the X direction (the X direction as viewed in FIG. 2A) as viewed in the figures by element isolation regions Sb. First insulating film 3 is provided above element regions Sa and polycrystalline silicon film 4 serving as the first conductive layer is further provided thereabove. Boron for example is introduced as impurities into polycrystalline silicon film 4.

The recesses formed into silicon substrate 2 of element isolation regions Sb is filled with element isolation insulating film 16. The upper surface of element isolation insulating film 16 is substantially level with the mid height of polycrystalline silicon film 4. Second insulating film 5 is formed along the surfaces of polycrystalline silicon film 4 and element isolation insulating film 16 so as to cover them. Polycrystalline silicon films 6 and 7 and metal film 8 are provided above element isolation insulating film 16. Silicon nitride film 9 is formed in the upper portion of metal film 8.

Next a description will be given on the structure of word line transfer transistor TrP with reference to FIG. 3C. FIG. 3C is one example of a figure illustrating the cross-sectional structure of the portion taken along line 3C-3C of FIG. 2B. Rectangular element regions Saa are defined in silicon substrate 2 by element isolation regions Sbb filled with element isolation insulating film 16.

Gate electrode PG of word line transfer transistor TrP is formed in the upper portion of a high-breakdown-voltage gate insulating film 17 formed above the upper surface of silicon substrate 2. Gate insulating film 17 is formed in a thickness capable of serving as a high-breakdown-voltage transistor which is thicker than gate insulating film 3. Types of transistors having gate insulating films equal in thickness to gate insulating film 3 of memory cell transistor Trm are provided in the peripheral circuit as well. Semiconductor elements other than transistors such as resistors or capacitors are also provided in the peripheral circuit.

Gate electrode PG is provided with polycrystalline silicon film 4 provided above gate insulating film 17, interelectrode insulating film 5, and polycrystalline silicon films 6 and 7, and metal film 8 serving as an upper electrode. Silicon oxide film 9 is stacked above metal film 8. Insulating film 10, such as a silicon oxide film used for gap formation, is formed above silicon oxide film 9. Opening 5b is provided in the central portion of interelectrode insulating film 5 of gate electrode PG, and polycrystalline silicon films 4 and 6 contacting one another are rendered electrically conductive. Thus, the lower electrode films and the upper electrodes films are provided so as to have the same potential.

Recess R1 is dug into the surface portion of silicon substrate 2 located between two gate electrodes PG. Recess R1 is lower than the surface portions of silicon substrate 2 located outside the two gate electrodes PG by depth d1. Recess R1 has sloped surface portions R1a at the end portions of gate electrode PG and planar surface Rib located between sloped surface portions R1a. Sloped surface portions R1a may be provided to exhibit a taper angle (sloped angle) of θ1 relative to the surface of silicon substrate 2 ranging for example from 10 degrees to 80 degrees. Further, depth d1 corresponding to the amount of recess of planar surface Rib of recess R1 may be specified to range for example from 10 to 100 nm.

Source/drain region 2d doped with impurities and heavily-doped impurity region 2e are provided in the portions of the surface of silicon substrate 2 exclusive of gate electrodes PG. Silicon oxide film 12 and silicon nitride film 13 serving as liner films are provided along the upper surfaces and the side surfaces of gate electrodes PG and the surface of silicon substrate 2 so as to cover them. Interlayer insulating film 14 is formed above the entire surface to fill the gaps between gate electrodes PG.

Contact plugs 15a to 15c are provided so as to extend through interlayer insulating film 14 from the upper portion to the lower portion thereof and further through silicon nitride film 13 and silicon oxide film 12 to establish ohmic contacts with three source/drain regions 2d of silicon substrate 2, respectively. As illustrated in FIG. 2B, contact plugs 15a to 15c are provided in twos, but may be provided in ones, or in threes or more.

Wiring layer 18 is provided above the upper surface of interlayer insulating film 14 to establish contact with word lines, etc. Wiring layer 18 is patterned to have wirings extending in the X direction which are spaced by a predetermined distance in the Y direction. Wiring layer 18 is configured to be capable of connecting with word lines WL drawn from the memory cell region. Interlayer insulating film 19 is provided above the upper surface of wiring layer 18 so as to cover wiring layer 18 and interlayer insulating film 14.

In the above described structure, contact plugs 15a and 15c connected to source/drain regions 2d located in the outer sides of two word line transfer transistors TrP serve as electrodes of word line WL side of the memory cell region. Contact plugs 15a and 15c are electrically connected to word lines WL of the memory cell region through the wirings of wiring layer 18. Contact plug 15b of the middle source/drain region 2d shared by the two word line transfer transistors TrP serves as an electrode connected to the wiring (CG line) of the peripheral circuit side. Contact plug 15b is electrically connected to the peripheral circuit via the wiring of wiring layer 18. Other wirings of wiring layer 18 are connected to word lines WL of other transfer transistors TrP.

Recess R1 is provided in the surface of silicon substrate 2 of source/drain region 2d of word line transfer transistors TrP connected to contact plug 15b. It is thus, possible to increase the distance between source/drain region 2d and CG line of wiring layer 18 as compared to a structure which is not provided with recess R1. As a result, it is possible to inhibit impact ionization by relaxing the electric field originating from the voltage applied between them. It is possible to inhibit the depletion of the source/drain region and consequently suppress current degradation after the programming operation and erasing operation by increasing the distance between source/drain region 2d and wiring layer 18 facing it.

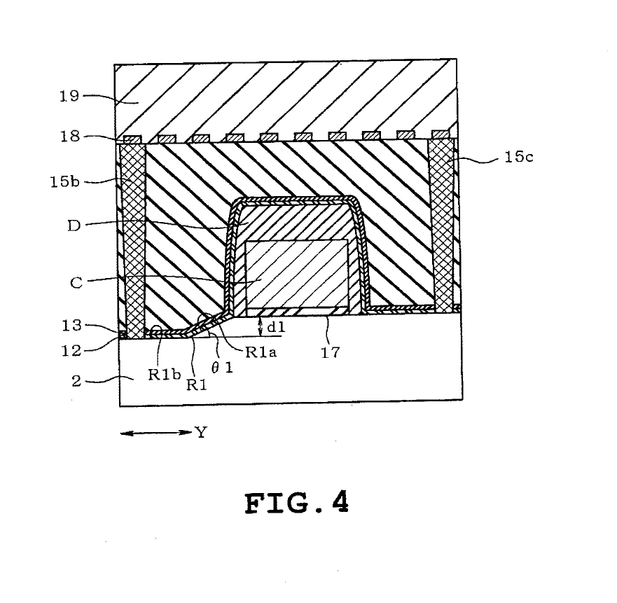

Next, a description will be given on the result of simulation performed for verifying the above described results. The simulation employs the simulation model indicated in FIG. 4. In the simulation model, polycrystalline silicon film 4, interelectrode insulating film 5, polycrystalline silicon films 6 and 7, and metal film 8 are considered as a structurally integral conductor C having the same potential. Further spacer 11, provided along the sidewalls of silicon oxide film 9 above metal film 8, insulating film 10, and gate electrode PG, are considered as a structurally integral silicon oxide film D.

Various properties have been simulated using taper angle θ1 and depth d1 as parameters, where θ1 represents the taper angle (sloped angle) of slopes R1a and d1 represents the depth (the amount of recess) of planar portion R1b of recess R1 in the surface of silicon substrate 2.

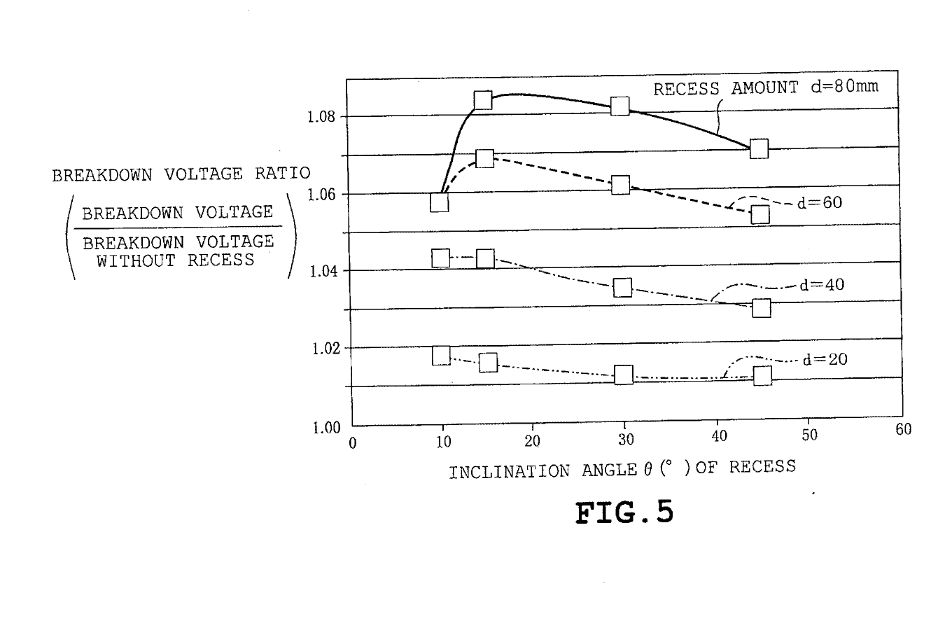

Simulations of breakdown voltages are obtained when a high voltage corresponding to the programming voltage (VPGM) is applied to CG line in word line transfer transistor TrP, that is, when a high voltage is applied to contact plug 15b. The results are indicated in FIG. 5. In the results indicated in FIG. 5, recess amount d1 is plotted in four levels of 20 nm, 40 nm, 60 nm, and 80 nm and taper angle θ1 of recess R is specified in four levels of 10 degrees, 15 degrees, 30 degrees, and 45 degrees.

According to the results indicated in FIG. 5, greater improvement is achieved in the breakdown voltage at larger depth d1 which represents the recess amount. Further, with respect to taper angle θ1, the breakdown voltage tend to saturate near 10 degrees when depth d1 is equal to or greater than 60 nm and higher breakdown voltage is obtained as depth d1 becomes greater when taper angle θ1 is equal to or greater than 15 degrees, peaking at 15 degrees. The improvement of breakdown voltage is presumed to be attributable to the suppressed impact ionization owning to the relaxed electric field near the edges of gate electrodes PG. Stated differently, suppressed impact ionization reduces the amount of electrons being produced which means that the possibility of the electrons being trapped in silicon nitride film 13 used as the liner film is reduced.

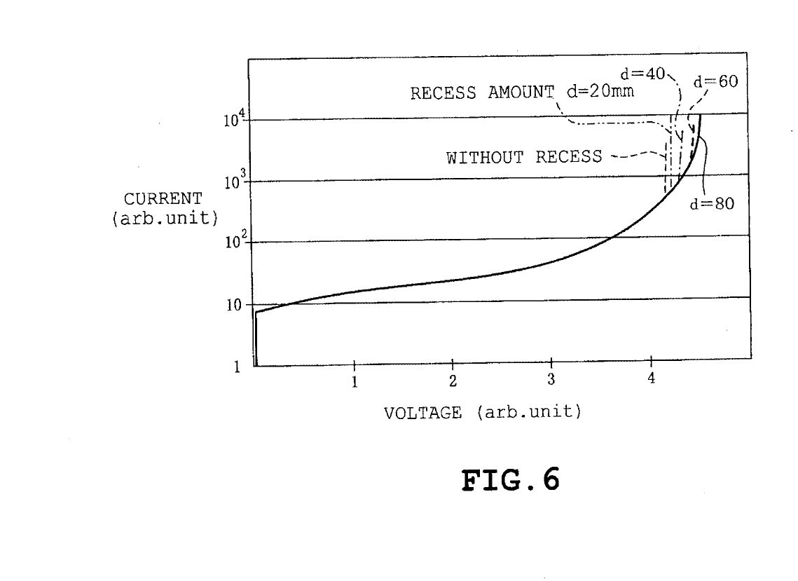

FIG. 6 indicates the calculated result of voltage-current property when recess R1 in source/drain region 2d connected to CG line exhibits taper angle θ1 of 15 degrees and recess depth d1 of 60 nm. As the voltage level is being elevated, the voltage value at which the current value marks a sudden increase indicates the breakdown voltage. Similar calculation results for a word line transfer transistor which is not provided with recess R1 is also given for comparison. It was verified from the results that, elevation of 1V or greater was observed in the structure of the present embodiment provided with recess R1 as compared to a structure in which recess R1 is not provided.

Approximately 9% of degradation was observed in the current value of word line transfer transistor TrP provided with recess R1 as compared to the current value of a word line transfer transistor not provided with recess R1 in the state before the programming and erasing. However, current degradation occurring after the programming and the erasing is expected to improve in word line transfer transistor TrP provided with recess R1 since reduction in the amount of electrons trapped in silicon nitride film 13 serving as a liner film is achieved and the distance between wiring layer 18 and source/drain region 2d connected to CG line is increased by the depth of recess R1.

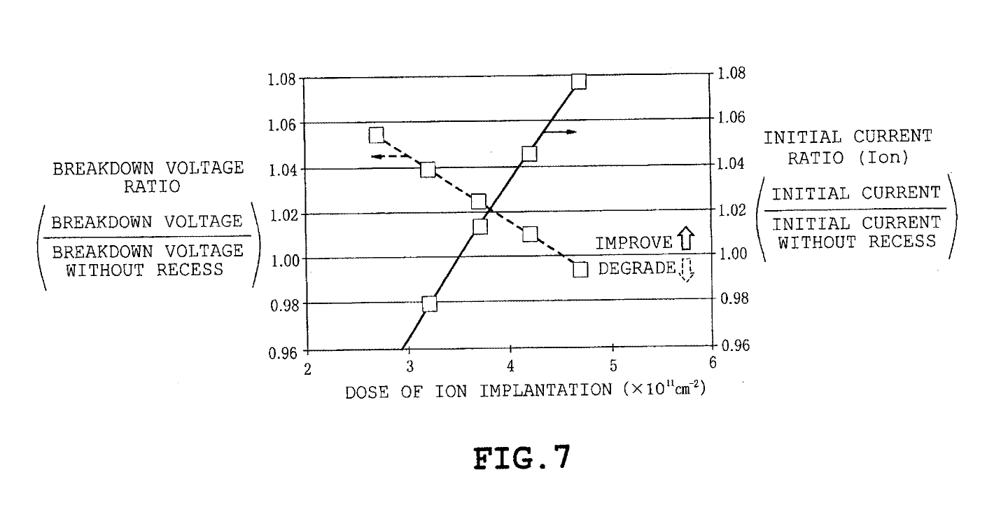

FIG. 7 indicates the result of examination on how increased dose of ion implantation affects the breakdown voltage (V) and initial current Ion (A), for the purpose of suppressing current value degradation occurring before programming and erasing in word line transfer transistor TrP provided with recess R1. The breakdown voltage was measured based on a configuration in which the current value was adjusted to be equal to the current value of a word line transfer transistor TrP which is not provided with recess R1, by varying the dose for forming the N-type diffusion layer serving as source/drain region 2d. The breakdown voltage is represented as a ratio to the breakdown voltage of a structure not provided with recess R1.

Thus, the improvement of the breakdown voltage becomes greater as the breakdown voltage becomes increasingly greater than 1.00. The value of initial current Ion obtained under the same conditions is also represented as an initial current ratio. As a result, the breakdown voltage tends decrease as the amount of ion implantation increases, however, improvement is observed in the initial current ratio. Further, as indicated in FIG. 7, it is possible to improve initial current while maintaining the breakdown voltage at or greater than the level (=1.00) of the case without recess R1.

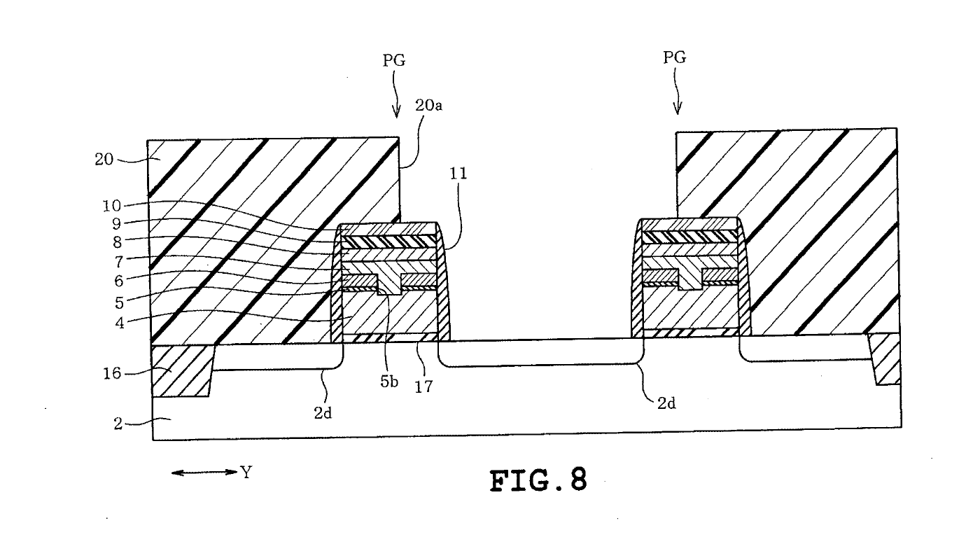

Next, a description will be given on the process steps for forming recess R1 in word line transfer transistor TrP among the foregoing structures with reference to FIGS. 8 to 10. The following description of the present embodiment will focus on the process steps for forming recess R1. Though descriptions on the process steps for forming memory cell transistors in the memory region will not be given, known process steps may be added between the process steps or some of the process steps described hereinafter may be removed. Further, the process steps may be rearranged if practicable.

First a description will be given briefly on the process steps for obtaining the state illustrated in FIG. 8. Gate insulating film 17, polycrystalline silicon film 4, and an insulating film serving as a work film are formed above the upper surface of silicon substrate 2. Then, anisotropic etching using RIE is performed to form element isolation regions Sb and Sbb by lithography. As a result, the insulating film serving as a work film, polycrystalline silicon film 4, and gate insulating film 3 or gate insulating film 17 are removed one after another to form element isolation trenches into silicon substrate 2. The formed element isolation trenches are filled with a coating-type silicon oxide film. It is thus, possible to form element isolation insulating film 16 in the element isolation trenches. Then, the insulating film serving as the work film is removed by hot phosphoric acid or the like. Element isolation regions Sa and Saa as wells as element isolation regions Sb and Sbb are defined in this process step.

Next, interelectrode insulating film 5 and polycrystalline silicon film 6 are formed. Interelectrode insulating film 5 may be formed of for example an ONO film. Polycrystalline silicon film 6 may be formed of for example CVD. Then, boron for example may be introduced into polycrystalline silicon film 6 by ion implantation to obtain a p-type polycrystalline silicon.

Thereafter, polycrystalline silicon film 6 and interelectrode insulating film 5 are partially and selectively removed using lithography to form openings 5a and 5b in the portions corresponding to gate electrodes SG of select gate transistors Trs and portions corresponding to gate electrodes PG of word line transfer transistors TrP and other transistors in the peripheral circuit.

Then, undoped polycrystalline silicon film 7 is formed above the entire surface using CVD and boron for example is introduced by ion implantation to obtain a p-type polycrystalline silicon. Polycrystalline silicon film 7 is placed in contact with polycrystalline silicon film 4 via openings 5a and 5b. As a result, polycrystalline silicon film 4 becomes electrically conductive with polycrystalline silicon film 6 and polycrystalline silicon film 7.

Then, metal film 8 and silicon nitride film 9 are formed one after another. Metal film 8 may be formed for example by forming tungsten (W) by sputtering. Silicon nitride film 9 may be formed by CVD. In this example, tungsten nitride (WN) or the like, serving as a barrier film may be formed between polycrystalline silicon film 7 and metal film 8.

In the foregoing description, formation of polycrystalline silicon films 6 and 7 are carried out by forming a polycrystalline silicon film free of impurities and thereafter introducing boron into polycrystalline silicon by ion implantation. The following method of formation may be employed instead. A method may be employed in which the polycrystalline silicon film is formed by CVD while introducing boron for example as impurities to obtain a polycrystalline silicon film doped with impurities.

Next, gate electrodes MG of memory cell transistors Trm are formed by a process using lithography and insulating film 10 is formed by forming a silicon oxide film or the like under conditions providing poor gap fill capabilities to form air gaps between gate electrodes MG of memory cells.

Thereafter, processing for select gate transistors and transistors in the peripheral circuit is carried out. A mask pattern used as an etch mask is formed by lithography. Then, anisotropic etching is performed using RIE. In the anisotropic etching, insulating film 10 used for forming gaps, silicon nitride film 9, metal film 8, polycrystalline silicon films 7 and 6, interelectrode insulating film 5, and polycrystalline silicon film 4 are removed one after another.

Next, phosphorous for example is lightly doped into the source/drain regions of n-channel transistors of word line transfer transistors TrP in the peripheral circuit using photolithography and ion implantation. Similarly, boron for example is lightly doped into the source/drain regions of p-channel transistors. It is thus, possible to form lightly-doped source/drain region 2d in an LDD structure of a transistor.

Then, an insulating film such as a silicon oxide film is formed in a predetermined thickness by CVD under conditions providing good coverage. Thereafter, the insulating film is etched back by anisotropically etching the entire surface by RIE and spacers 11 are formed along the side surfaces of gate electrodes SG and PG extending from the height of the upper surfaces of gate electrodes SG and PG to the height of the surface of silicon substrate 2.

Next, photoresist 20 is coated above the upper surface of the above described structure using lithography and opening 20a is patterned so as to expose source/drain region 2d located between two gate electrodes PG. In this example, opening 20a is patterned so that the edges of the pattern run along the upper surfaces of gate electrodes PG. The structure illustrated in FIG. 8 is obtained in the above described manner.

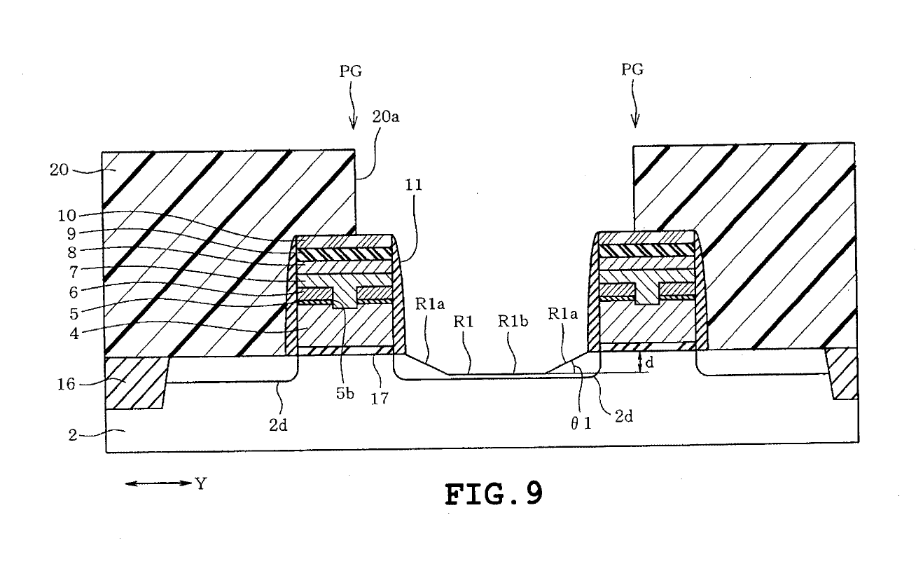

Then, using photoresist 20 as a mask, recess R1 is formed into source/drain region 2d of silicon substrate 2 exposed by opening 20a as illustrated in FIG. 9. Recess R1 is formed by controlling the etching conditions of silicon in anisotropic etching such as RIE (Reactive Ion Etching). In this example, the upper surfaces and side surfaces of gate electrodes PG exposed by opening 20a of photoresist 20 are covered by materials primarily comprising silicon oxide film. It is thus, possible to selectively etch the surface of silicon substrate 2. The etching forms recess R1 having sloped surface portions R1a having taper angle θ1 at the end portions of gate electrodes PG and planar portion R1b having depth d1 between sloped surface portions R1a.

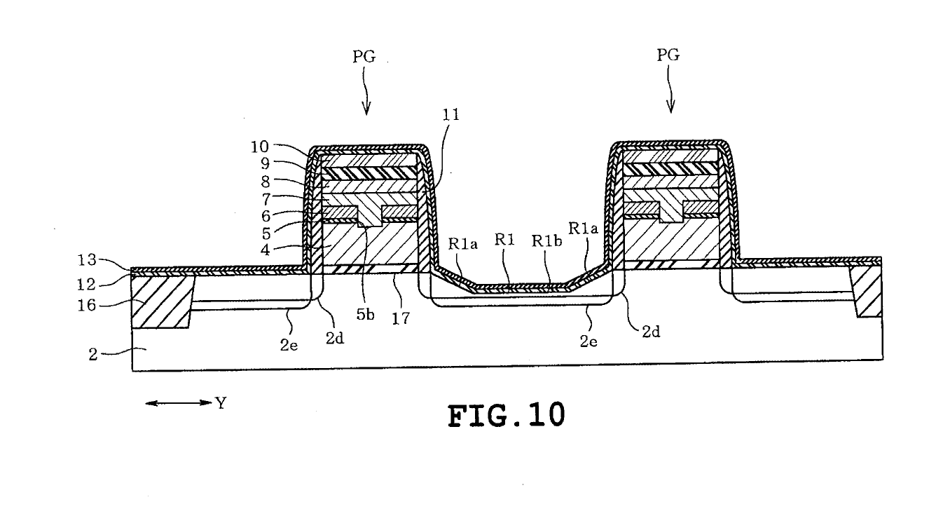

Next, impurities are introduced into the source/drain region located between gate electrodes PG by ion implantation as illustrated in FIG. 10. Boron is heavily doped as impurities in this example. The impurities introduced by ion implantation are not introduced in the portions where spacers 11 are provided. As a result, it is possible to form heavily doped source/drain region 2e in an LDD structure of a transistor.

Then, silicon oxide film 12 and silicon nitride film 13 serving as liner films are formed one after another along the upper surfaces and side surfaces of gate electrodes PG and along the surface of silicon substrate 2. Thus, the upper surfaces of gate electrodes PG, the surfaces of spacers 11, and the upper surface of silicon substrate 2 are covered by silicon oxide film 12 and silicon nitride film 13. Silicon oxide film 12 and silicon nitride film 13 are further formed along the upper surface of insulating film 10 for forming gaps in the memory cell region and along the side surfaces of spacers 11 formed in the portions where select gate transistors Trs face one another as well as the surface of silicon substrate 2.

Next, interlayer insulating film 14 is formed above the upper surface of silicon nitride film 13 formed in the above described process step as illustrated in FIG. 3C. Interlayer insulating film 14 fills the recesses created by the undulations of gate electrodes PG and silicon substrate 2 to obtain a structure having a flat upper surface. Interlayer insulating film 14 is formed so as to also fill the recesses located in the portions where gate electrodes SG of the select gate transistors Trs face one another. Planarization may be achieved by performing CMP after interlayer insulating film 14 is formed.

Then, contact holes are formed into interlayer insulating film 14 by anisotropic etching using RIE. In this example, contact holes associated with select gate transistors Trs in the memory cell region are formed simultaneously in addition to the contact holes associated with contact plugs 15a to 15c. The contact holes are formed so as to extend from the upper surface of interlayer insulating film 14 to the surface of silicon substrate 2. The contact hole corresponding to contact plug 15b and being formed in the portion where recess R1 is formed is deeper than other contact holes, and thus, the etching reaches the upper surface of silicon nitride film 13 later than other contact holes. Silicon nitride film 13 may serve as a etch stopper in the RIE etching by applying conditions in which silicon nitride film 13 is not easily etched. It is thus, possible to simultaneously form contact holes having different depths.

This is followed by formation of contact plugs 15a to 15c and formation of other contact plugs. Contact plugs 15a to 15c are formed by forming a metal film along the upper surface of the structures subjected to the above described processing and removing the metal film located above interlayer insulating film 14 by etch back or CMP while leaving the metal film inside the contact holes. Tungsten (W) film using titanium nitride (TiN) as a barrier film may be used for example in contact plugs 15a to 15c. Contact plugs 15a to 15c may be formed by the above described process steps.

This is followed by formation of wiring layer 18 for establishing electric contact with contact plugs 15a to 15c, etc. and formation of interlayer insulating film 19 for further covering wiring layer 18. Wiring layer 18 is formed of tungsten film for example and is patterned by lithography. Interlayer insulating film 19 is formed so as to cover the formed wiring layer 18. A silicon oxide film may be used for example for forming interlayer insulating film 19. Word line transfer transistors TrP are formed in the above described manner.

In the present embodiment described above, recesses R1 are provided in silicon substrate 2 located in source/drain regions 2d of word line transfer transistors TrP connected to electrodes (CG lines) located in the peripheral circuit side by way of contact plugs 15b. It is thus, possible to increase the effective distance between gate electrodes PG and CG lines in the peripheral circuit side. It is further possible to increase the distance between wiring layer 18 extending over source/drain diffusion regions 2d connected to CG lines and source/drain diffusion region 2d. As a result, it is possible for word line transfer transistor TrP to improve the breakdown voltage against high voltage stress applied in the programming and suppress current degradation after the programming and the erasing.

In the present embodiment, an example in which word line transfer transistors TrP are provided in pairs are discussed. However, word line transfer transistor TrP may be provided alone or in further greater numbers.

### Second Embodiment

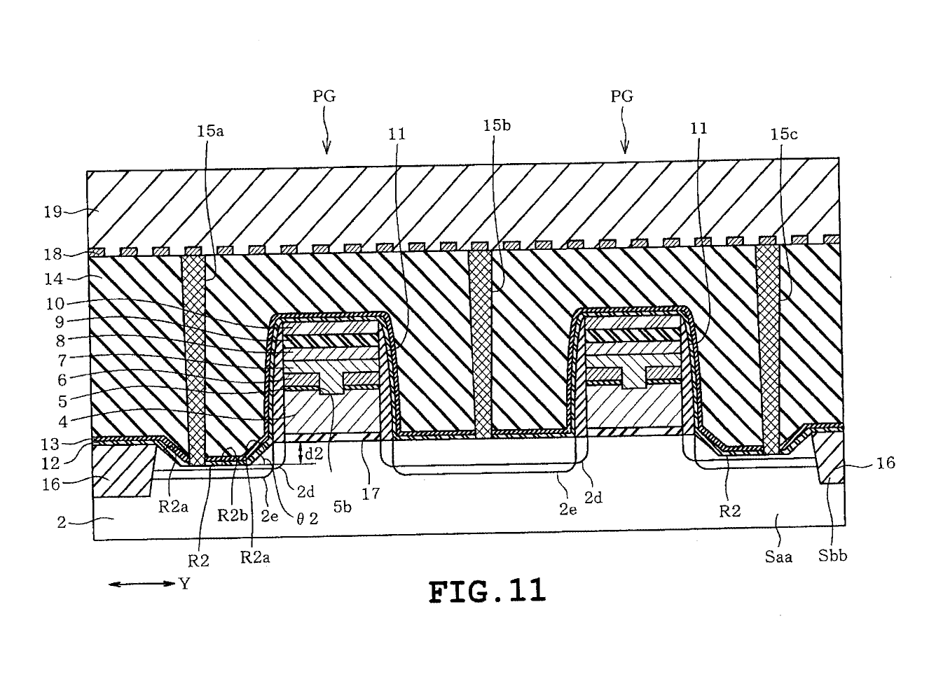

FIGS. 11 to 14 illustrate a second embodiment. In this embodiment, recess R2 is provided in a portion different form the first embodiment. In this example, recess R2 is provided in source/drain regions 2d where contact plugs 15a and 15c are provided. In this embodiment, word line transistor TrP is configured to be capable of improving the stress during erasing.

In word line transfer transistors TrP, recesses R2 are formed in the surfaces of silicon substrate 2 of source/drain regions 2d connected to contact plugs 15a and 15c which are connected to word lines WL of memory cell transistors Trm as illustrated in FIG. 11. In this example, sloped surface portions R2a are provided at each of the end portions of gate electrodes PG and element isolation insulating films 16 and planar surfaces R2b are provided between sloped surface portions R2a. Sloped surface portion R2a is provided to exhibit a taper angle (taper angle) of θ2 relative to the surface of silicon substrate 2. Further, planar surface R2b of recess R2 is provided to exhibit depth d1 corresponding to the amount of recess.

As described above, the surface of silicon substrate 2 becomes lower than the silicon surfaces of source/drain regions 2d connected to electrodes (CG lines) located in the peripheral circuit side by providing recesses R2 in source/drain regions 2d of contact plugs 15a and 15c. As a result, it is possible to increase the effective distance between gate electrodes PG and word lines WL and thereby relax the electric field between the foregoing to inhibit impact ionization. It is further possible to suppress current degradation after programming and erasing by increasing the distance between wiring layer 18 located above source/drain regions 2d and source/drain regions 2d connected to word lines WL.

The increased effective distance between gate electrodes PG and word lines WL enables relaxation of electric field compared to word line transfer transistor which is not provided with recess R2 in an electric field distribution resulting from application of high voltage corresponding to the erase voltage (VERA) to word line WL side. That is, current degradation occurring after programming and erasing can be improved as was the case in the first embodiment.

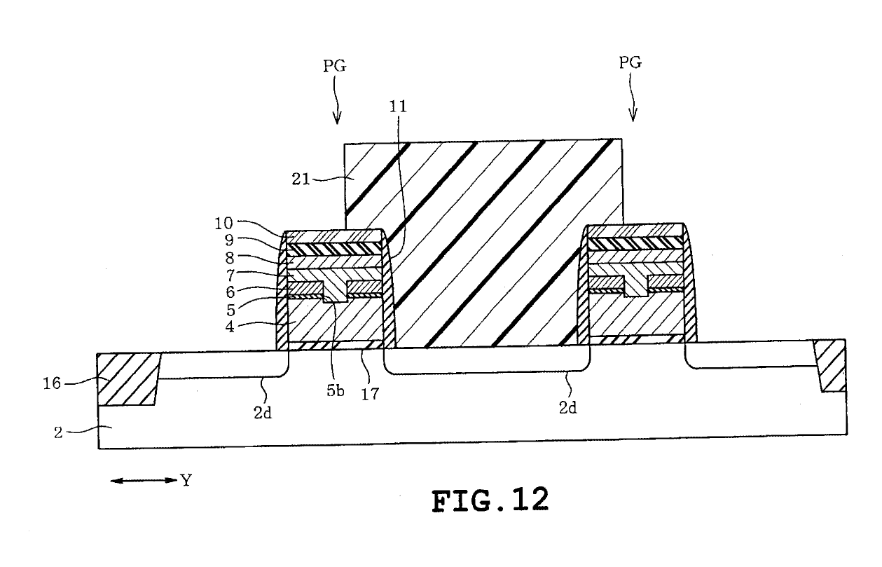

Next, a description will be given on the process steps for forming recess R2 in word line transfer transistor TrP among the above described structures with reference to FIGS. 12 to 14. The following description of the present embodiment will focus on the process steps for forming recess R2. The process steps up to the formation of recess R2 are similar to those of the first embodiment and thus will not be given. Known process steps may be added between the process steps or some of the process steps described hereinafter may be removed. Further, the process steps may be rearranged if practicable.

First, element regions Sa and Saa as well as element isolation regions Sb and Sbb are formed in silicon substrate 2, gate electrodes PG are formed in element regions Saa, and spacers 11 are formed along the sidewalls of gate electrodes PG as illustrated in FIG. 12.

Next, photoresist 21 is coated above the upper surface of the above described structure using lithography, and photoresist 21 is patterned so as to cover source/drain region 2d located between two gate electrodes PG. In this example, edges of the patterned photoresist 21 run along the upper surfaces of gate electrodes PG. The structure illustrated in FIG. 12 is obtained in the above described manner.

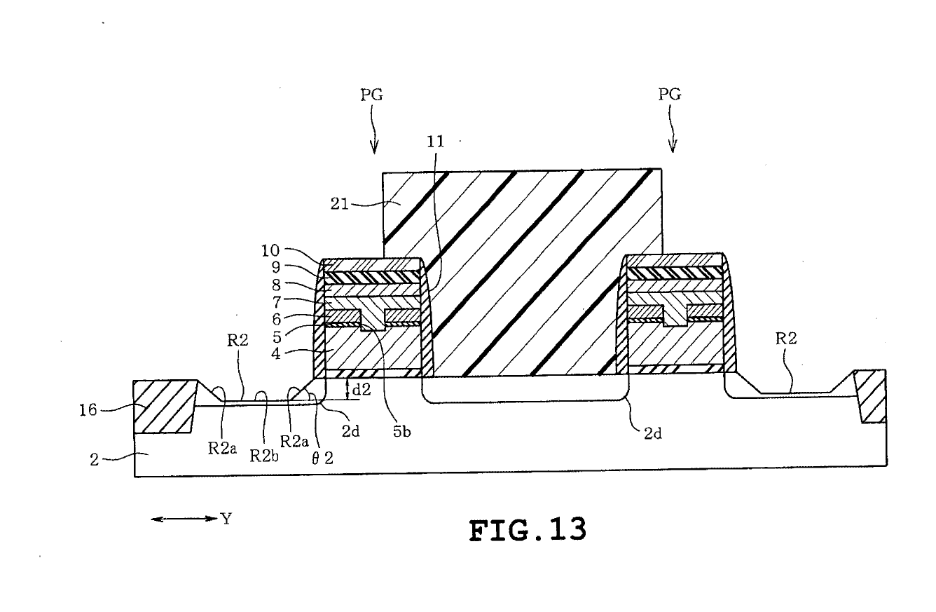

Then, using photoresist 21 as a mask, recesses R2 are selectively formed into two source/drain regions 2d of silicon substrate 2 exposed in the outer sides of two gate electrodes PG as illustrated in FIG. 13. Recesses R2 are formed by controlling the etching conditions in anisotropic etching such as RIE. The etching forms recesses R2 having sloped surface portions R2a having taper angle θ2 at the end portions of gate electrodes PG and the end portions of element isolation insulating film 16 and planar portions R2b having depth d2 between sloped surface portions R2a.

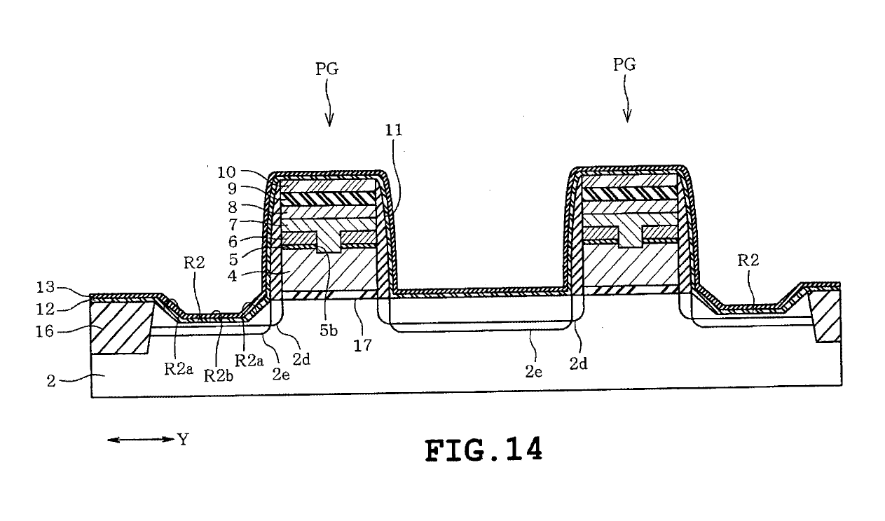

Next, impurities are introduced into source/drain regions 2d located between gate electrodes PG by ion implantation as illustrated in FIG. 14. Boron is heavily doped as impurities in this example. The impurities introduced by ion implantation are not introduced in the portions where spacers 11 are provided. As a result, it is possible to form heavily doped source/drain region 2e in an LDD structure of a transistor. Then, silicon oxide film 12 and silicon nitride film 13 serving as liner films are formed one after another along the upper surfaces and side surfaces of gate electrodes PG and along the surface of silicon substrate 2 as was the case in the first embodiment.

Next, interlayer insulating film 14, contact plugs 15a to 15c, wiring layer 18, interlayer insulating film 19, and the like are formed above or into the upper surface of silicon nitride film 13 formed in the above described process step as illustrated in FIG. 11. As a result, word line transfer transistor TrP structured as illustrated in FIG. 11 is formed.

In the above described structure, it is possible to inhibit impact ionization by relaxing the electric field between gate electrodes PG and word lines WL by providing recesses R2 in source/drain regions 2d of contact plugs 15a and 15c and thereby suppress current degradation after programming and erasing. As a result, it is possible to improve current degradation after programming and erasing as was the case in the first embodiment.

The structures of the above described embodiment may be applied to the first embodiment. Recesses R1 and R2 are provided in the three source/drain regions 2d of word line transfer transistors TrP formed in a pair. In this example, it is possible to obtain the effects of the first embodiment and the second embodiment. In this example, portions other than the regions for forming recesses R1 and R2 may be covered by a resist film so that other transistors are not affected by the formation of the recesses.

Further in the manufacturing process steps of the above described embodiments, selective etching is performed by patterning resist film 20 or 21 when forming recess R1 or R2. However, when the recesses are formed in the level of recess amount which does not affect the properties of the transistors other than word line transfer transistor TrP, a manufacturing process flow may be employed in which masks formed of resist films are not used.

Further in the above described embodiment, an example in which word line transfer transistors TrP are provided in pairs are discussed. However, word line transfer transistor TrP may be provided alone or in further greater numbers.

### Third Embodiment

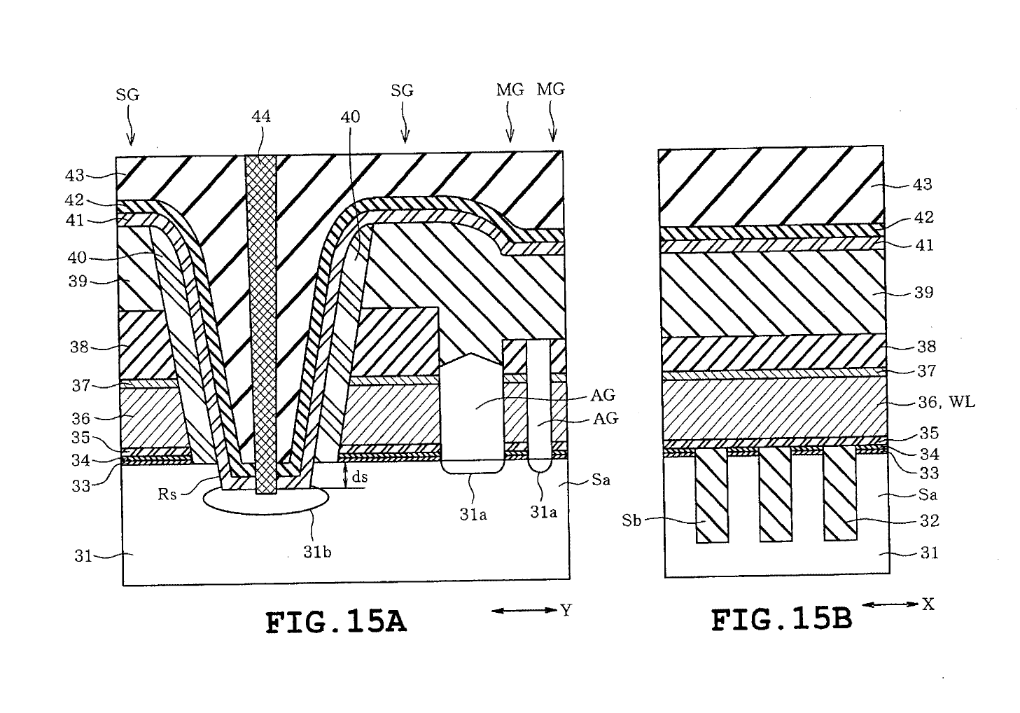

FIGS. 15 to 21 illustrate a third embodiment. The present embodiment is described through an example employing a flat-cell type memory cell in which a floating gate is provided in a select gate transistor. In the NAND flash memory device of the present embodiment, the memory cell exhibits a flat cell structure, however, the planar layout is similar to the layout illustrated in FIG. 2A and thus, a description will not be given for the same.

FIGS. 15A and 15B are each one example of a vertical cross-sectional view illustrating the portion taken along line 15A-15A and line 15B-15B in FIG. 2A illustrating the layout of the memory cell region.

In FIGS. 15A and 15B, multiple element isolation trenches are formed into the upper portion of silicon substrate 31 of the memory cell region so as to be spaced from one another in the X direction by a predetermined distance. The element isolation trenches are filled with element isolation insulating film 32. Thus, element isolation regions Sb are formed along the Y direction and isolate the surface layer portion of semiconductor substrate 31 in the X direction to form a plurality of element regions Sa.

Gate electrode MG of memory cell transistor Trm is provided above gate insulating film 33 formed above silicon substrate 31. Source/drain regions 31a are formed in the surface layer portion of silicon substrate 31 located on both sides of gate electrode MG. Further, recess Rs is formed in the surface layer portion of semiconductor substrate 31 located between gate electrodes SG by lowering the surface layer by depth ds. Source/drain regions 31b is formed in the region of recess Rs.

Memory gate electrode MG and select gate electrode SG are configured by stacking polycrystalline silicon film 4 serving as a charge storing layer, interelectrode insulating film 35, polycrystalline silicon film 36 serving as a control gate electrode, metal layer 37, and insulating film 38 such as a silicon oxide film one after another above gate insulating film 33. Interelectrode insulating film 35 is formed as a stack of films such as a silicon nitride film and a hafnium film. The flat cell structure is obtained by providing polycrystalline silicon film 34 serving as a floating gate electrode (FG) as a thin film being approximately few nm.

Select gate electrode SG does not require floating gate electrode (FG) and may employ a structure in which polycrystalline silicon films 34 and 36 are short circuited. When employing a flat cell structure, however, polycrystalline silicon films 34 and 36 are used as they are considering the controllability of the process step for forming the short-circuited structure. This means that polycrystalline silicon film 34 is provided in a floating state being disposed between gate insulating film 33 and interelectrode insulating film 35.

Air gaps AG are not provided in the portions where gate electrodes SG face one another. Spacers 40 are provided along the side surfaces of gate electrodes SG. A silicon oxide film may be used for example as spacer 40 and may be formed so as to extend from the upper surface portion of gate electrode SG and reach the surface of silicon substrate 31. When forming spacer 40, the surface of silicon substrate 31 exposed between gate electrodes SG is over etched to provide recess Rs.

Silicon oxide film 41 and silicon nitride film 42 are formed one after another above insulating film 39 so as to cover the surface of insulating film 39, the surface of spacer 40 located between gate electrodes SG, and the surface of silicon substrate 31 exposed in the bottom surface portion. Silicon oxide film 41 and silicon nitride film 42 are formed so as to cover the surface of recess Rs located between gate electrodes SG. Interlayer insulating film 43 is formed above silicon nitride film 42 so as to fill the recesses between gate electrodes SG and cover the upper surfaces of gate electrodes MG and SG. Contact plug 44 extends through interlayer insulating film 43 from the upper portion to the lower portion thereof and further through silicon nitride film 42 and silicon oxide film 41 to reach silicon substrate 31 located in the bottom surface portion of recess Rs located between gate electrodes SG.

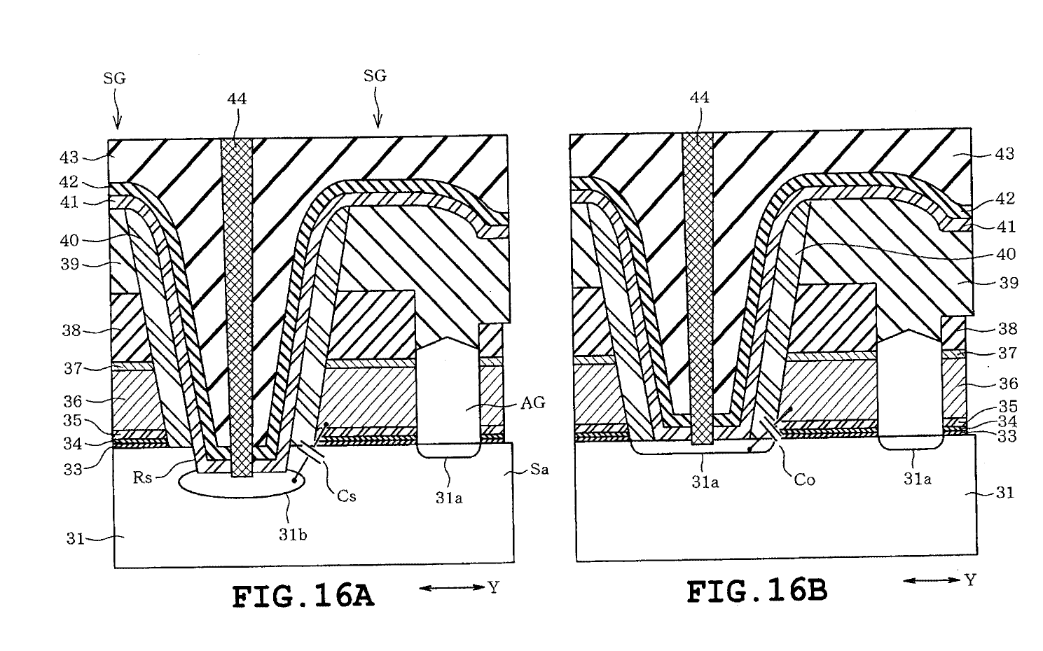

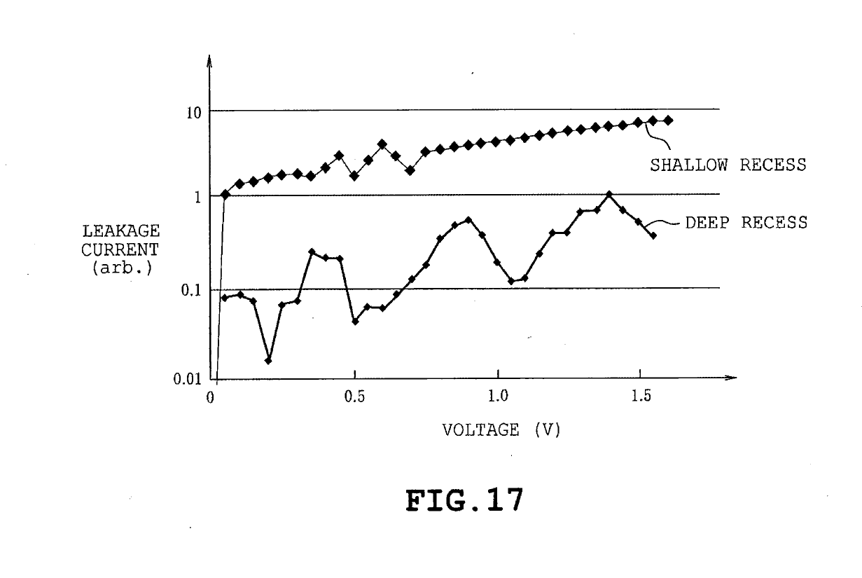

Next, the operation of the above described structure will be described with reference to FIGS. 16A, 16B, and 17. In the above described structure, contact plug 44 is provided so as to contact the bottom surface portion of recess Rs being lower than the upper surface of silicon substrate 31 as illustrated in FIG. 16A. As a result, it is possible to dispose source/drain region 31b, formed for reducing the resistance of the contact, to be distanced from gate electrode SG. As a result, it is possible to reduce the capacitance (overlap capacitance) CS between gate electrode SG and source/drain region 31b.

For comparison, FIG. 16B illustrates one example of a cross-sectional structure which not provided with recess Rs. In the structure illustrated in FIG. 16B, silicon substrate 31 located between gate electrodes SG is not provided with recess Rs. Thus, the diffusion region formed in this portion is source/drain region 31a which is similar to other source/drain regions 31a. As a result, capacitance (overlap capacitance) Co of the structure illustrated in FIG. 16B is greater than capacitance Cs of the structure illustrated in FIG. 16A (Cs<Co) since the distance between gate electrode SG and source/drain regions 31a is closer compared to the structure of the present embodiment.

It is thus, possible to reduce overlap capacitance Cs of select gate electrode SG in the structure of the present embodiment as compared to capacitance Co of the structure which is not provided with recess Rs. Thus, the structure of the present embodiment is capable of suppressing the leakage current in select gate electrode SG when voltage is applied to contact plug 44.

Suppressing leakage current in the above described structure achieves the following effects in the electrical operation of a memory. Consider a case where data is being written to memory cell transistor Trm. Transistor Trm in which data is written is referred to as the selected cell. The NAND string in which the selected cell is located is referred to as the selected bit line (selected BL). The bit line which is not selected are referred to as unselected bit line (unselected BL).

During the write operation, the nonselected bit line is placed in a floating state by turning off select gates SG on both ends so as to be in a boosted state in which no electric field is applied to gate insulating film 33. It is important to suppress the leakage current when in the boosted state, since the wrong cell may be written if the bit line is not electrically floated for the duration of programming pulse.

Among a number of causes of leakage current, failing to completely turn off gate electrode SG of select gate transistor Trs may create a current flow. In the flat cell structure illustrated in FIG. 15B, polycrystalline silicon film 34 of select gate electrode SG is insulated by gate insulating film 33 and interelectrode insulating film 35 and thus, in a floating state, the floating polycrystalline silicon film 34 is easily affected by voltage originating from (LI/CB) electrodes such as contact plug 44. Thus, the voltage level of polycrystalline silicon film 34 of select gate electrode SG is easily varied. This resembles a state in which gate bias is applied to select gate electrode SG and may cause unintended leakage current which may break the boosted state and lead to programming errors.

In this respect, polycrystalline silicon film 34 in the floating state is not easily affected by voltage originating from (LI/CB) electrodes such as contact plug 44 in the present embodiment even when a flat cell structure is employed as illustrated in FIG. 16A. It is thus, possible to suppress voltage variation in polycrystalline silicon film 34 of select gate electrode SG. As a result, it is possible to inhibit programming errors by suppressing occurrence of large levels of unintended leakage current at select gate electrode SG.

FIG. 17 indicates the results of simulated leakage current values when the amount of over etching is varied upon formation of recess Rs. As can be understood from the results, it has been verified that leakage current can be reduced more effectively as the amount of over etching increases, that is, as the depth of recess Rs becomes greater.

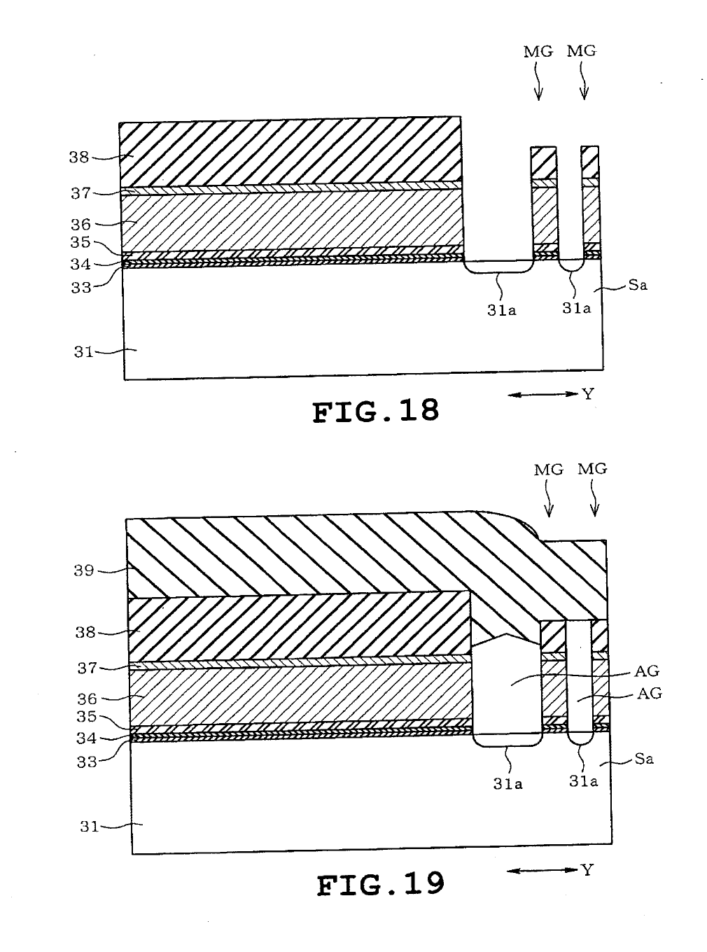

Next, a description will be given primarily on the process steps for forming select gate electrodes SG in the memory cell region among the foregoing structures with reference to FIGS. 18 to 21. The description of the present embodiment will focus on the process steps for forming recess Rs.

First a description will be given briefly on the process steps for obtaining the state illustrated in FIG. 18. Gate insulating film 33 is formed above the surface of silicon substrate 31, followed by formation of polycrystalline silicon film 34. Gate insulating film 33 serves as a tunnel insulating film which may be formed of a silicon oxide film for example. Polycrystalline silicon film 34 is formed for example by CVD (Chemical Vapor Deposition).

Then, an insulating film serving as a work film is formed above polycrystalline silicon film 34. Element isolation trenches are formed into silicon substrate 31 by lithography, and the element isolation trenches are filled with a coating-type silicon oxide film to form element isolation insulating film 32 and thereby provide element regions Sa and Saa as well as element isolation regions Sb and Sbb. The insulating film serving as working film is removed.

Next, interelectrode insulating film 35, polycrystalline silicon film 36, metal layer 37, and insulating film 38 such as a silicon oxide film are stacked one after another above the entire surface. Interelectrode insulating film 35 may be formed for example as a stack of films such as a silicon nitride film and hafnium film. Next, gate electrodes MG of memory cell transistors Trm are formed by a process using lithography. The processing of gate electrode MG is carried out by an anisotropic RIE etching using the resist pattern formed by lithography as an etch mask. The anisotropic etching removes insulating film 38, metal layer 37, polycrystalline silicon film 36, interelectrode insulating film 35, and polycrystalline silicon film 34 one after another. This process step also processes the side surfaces of gate electrodes SG of select gate transistors Trs facing memory cell transistors Trm.

Next, impurities are introduced into silicon substrate located between gate electrodes MG and between gate electrodes SG and MG by ion implantation. Phosphorous may be used as impurities. This process step forms source/drain region 31a of memory cell transistor Trm. The resulting structure is illustrated in FIG. 18.

Then, insulating film 39 for forming gaps is formed above the entire surface as illustrated in FIG. 19. Insulating film 39 for forming gaps may be formed of a silicon oxide film using CVD for example. In this example, insulating film 39 is formed under conditions providing poor coverage so as not to fill narrow regions. The spaces between gate electrodes MG of memory cell transistors Trm and the spaces between gate electrodes SG of select gate transistors Trs and gate electrodes MG are narrow.

Thus, as illustrated in FIG. 19, insulating film 39 is formed so as to provide a lid over the spaces between gate electrodes MG of memory cell transistors Trm and the spaces between gate electrodes SG of select gate transistors Trs and gate electrodes MG without filling spaces between gate electrodes MG of memory cell transistors Trm and the spaces between gate electrodes SG of select gate transistors Trs and gate electrodes MG.

As a result, air gaps AG unfilled with insulating film 39 are formed between gate electrodes MG of memory cell transistors Trm and between gate electrodes SG of select gate transistors Trs and gate electrodes MG. Air gaps AG reduce the wiring capacitance between gate electrodes MG.

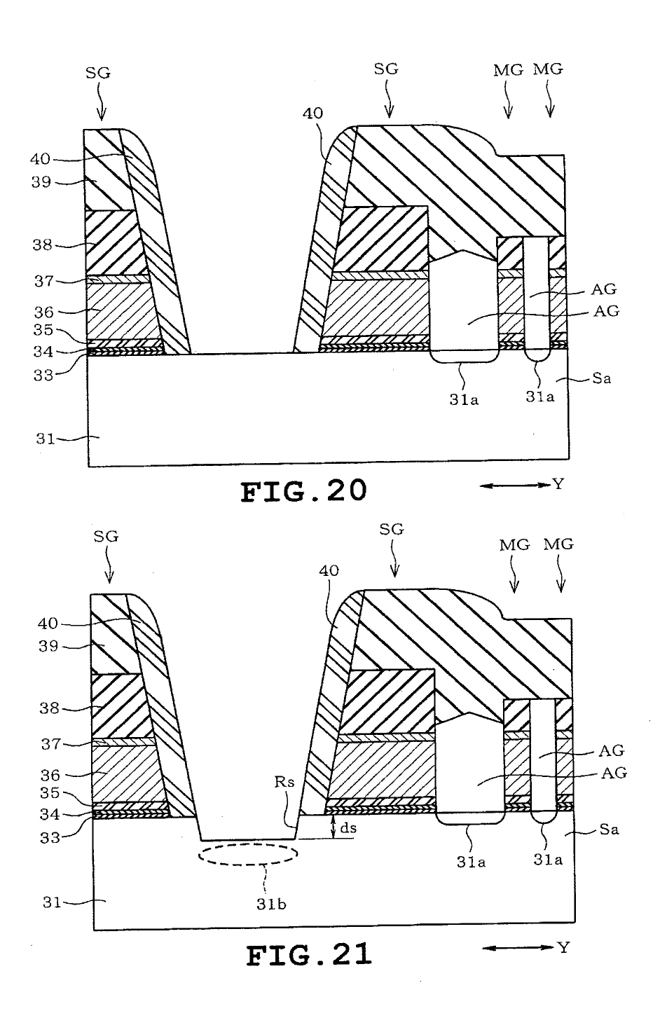

Next, gate electrodes SG of select transistors Trs are formed as illustrated in FIG. 20. The gate electrodes of the transistors in the peripheral circuit are also formed simultaneously in this process step. A mask pattern used as an etch mask is formed by lithography. Then, anisotropic etching is performed using RIE. In the anisotropic etching, insulating film 39 used for forming gaps, insulating film 38, metal film 37, polycrystalline silicon film 36, interelectrode insulating film 35, and polycrystalline silicon film 34, and gate insulating film 33 are removed one after another.

Then, an insulating film such as a silicon oxide film is formed in a predetermined thickness by CVD under conditions providing good coverage. Thereafter, the insulating film is etched back by anisotropically etching the entire surface by RIE and spacers 40 are formed along the side surfaces of gate electrodes SG extending from the height of the upper surfaces of gate electrodes SG to the height of the surface of silicon substrate 31. At this instance, the surface of silicon substrate exposed between select gate electrodes SG is further anisotropically etched to form recess Rs having depth ds.

By forming recess Rs, the height of the surface of silicon substrate 31 located between select gate electrodes SG becomes lower than the height of the surface of silicon substrate 31 located between select gate electrode SG and memory gate electrode MG or between memory gate electrodes MG. That is, the surfaces of silicon substrate 31 located on the two sides of select gate electrode SG are processed so that the surface in the select gate electrode SG side is lower than the surface in the memory gate electrode MG side.

Next, impurities such as phosphorous for example are introduced by ion implantation into the surface of source/drain region lowered by recess Rs and located in the portion where select gate electrodes SG face one another. Thus, source/drain region 31b is formed in a region lower than the surface of silicon substrate 31. The impurities in source/drain region 31b spreads to the region indicated by a solid line in FIG. 15A by diffusion caused by thermal treatment. In this state, the end portion of recess Rs in source/drain region 31b is spaced from the portion immediately under gate electrode SG by distance ds.

Then, as illustrated in FIG. 15A, silicon oxide film 41 and silicon nitride film 42 are formed one after another so as to cover the upper surface portion of the structures located above the upper surface of silicon substrate 31 having been subjected to the above described process steps. Silicon oxide film 41 and silicon nitride film 42 may be formed for example by CVD. As a result, the upper surface of insulating film 39 for forming gaps in the memory cell region, the side surfaces of spacers 40 formed in the portion where select gate electrodes SG face one another, and the surface of silicon substrate 31 are covered by silicon oxide film 41 and silicon nitride film 42.

Next, interlayer insulating film 43 is formed above the upper surface of silicon nitride film 42 formed in the above described process step. Interlayer insulating film 43 fills the recesses created by the undulations of gate electrodes SG and silicon substrate 31 to obtain a structure having a flat upper surface. Planarization may be achieved by performing CMP after interlayer insulating film 14 is formed. Further, contact hole is formed into interlayer insulating film 43 and the contact hole is filled with contact plug 44.

By employing the above described manufacturing process steps, it is possible to provide recess Rs by the over etching performed in the formation of spacer 40. It is thus, possible to form recess Rs easily and inexpensively without having to add dedicated process steps for forming recess Rs.

### Fourth Embodiment

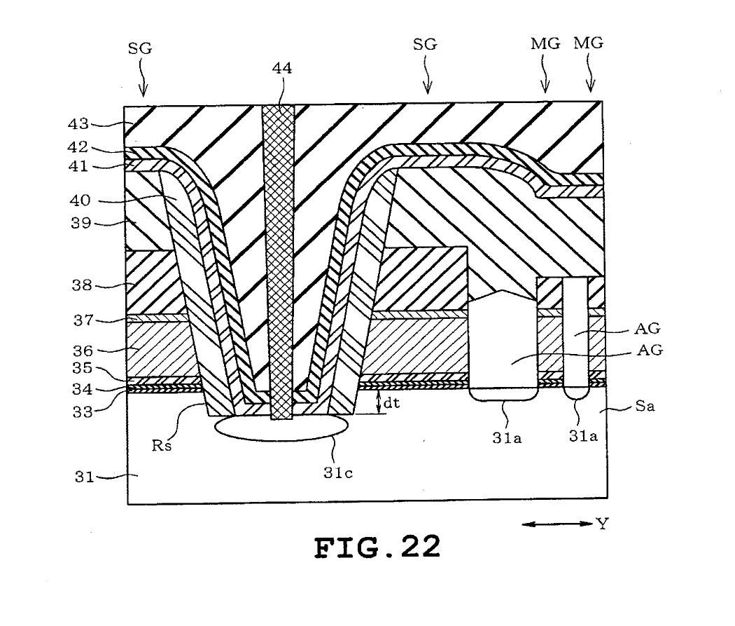

FIGS. 22 to 24 illustrate a fourth embodiment. The present embodiment employs a flat-cell type memory cell as was the case in the third embodiment.

FIG. 22 illustrate the portion corresponding to FIG. 15A and is one example of a vertical cross-sectional view taken along line 15A-15A of FIG. 2 illustrating the layout of the memory cell region. In this embodiment, recess Rt is formed instead of recess Rs in the surface of silicon substrate 31 located between select gate electrodes SG as illustrated in FIG. 22. The end portion of recess Rt is flush with the end portion of select gate. That is, in the third embodiment, recess Rs is formed when spacers 40 are formed; however, in the fourth embodiment, recess Rt is formed when the gate is processed. Thus, spacers 40 are formed so as to contact the inner bottom surfaces at the end portions of recess Rt.

Further, source/drain region 31c formed in recess Rt portion is provided substantially in the same state as source/drain region 31b since spacer 40 is formed even if the recess Rt may be relatively wider.

The above described structure allows source/drain region 31c, formed to reduce the resistance of contact, to be distanced from gate electrodes SG. As a result, it is possible to reduce the capacitance (overlap capacitance) between gate electrodes SG and source/drain region 31c. It is thus, also possible to obtain the effects similar to those obtained in the third embodiment in the present embodiment as well.

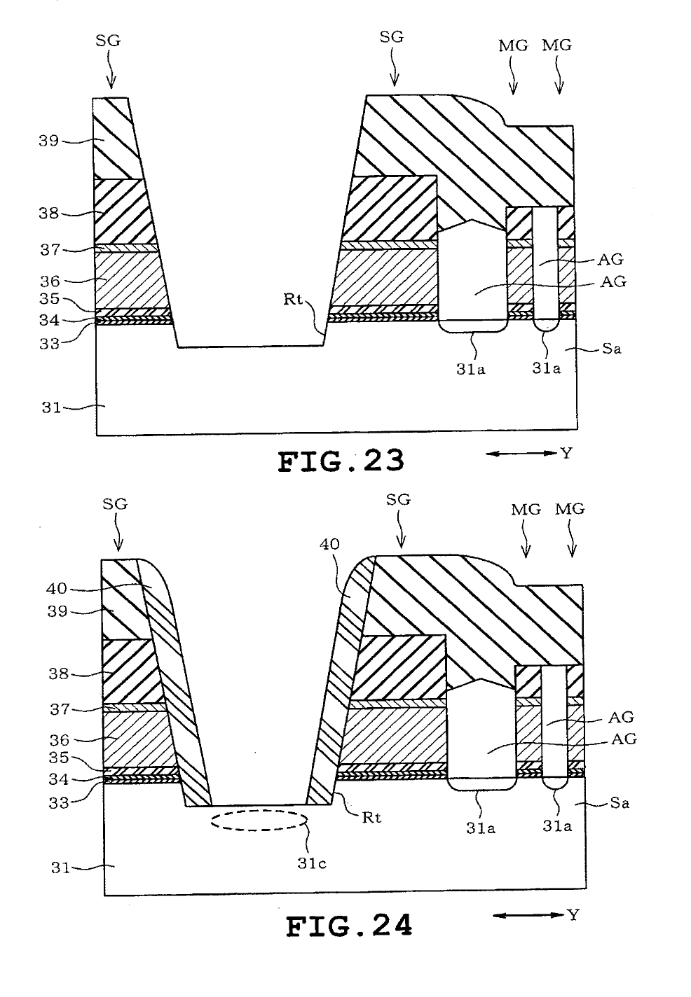

Among the process steps for obtaining the above described structure, FIGS. 23 and 24 illustrate the process steps for forming recess Rt. In the present embodiment, processes similar to those of the third embodiment are carried out to obtain the state illustrated in FIG. 19.

Next, gate electrodes SG of select transistors Trs are formed as illustrated in FIG. 23. The gate electrodes of the transistors in the peripheral circuit are also formed simultaneously in this process step. A mask pattern used as an etch mask is formed by lithography. Then, anisotropic etching is performed using RIE. In the anisotropic etching, insulating film 39 used for forming gaps, insulating film 38, metal film 37, polycrystalline silicon film 36, interelectrode insulating film 35, and polycrystalline silicon film 34, and gate insulating film 33 are removed one after another.

At this instance, the surface of silicon substrate 31 exposed between select gate electrodes SG is further anisotropically etched in the present embodiment to form recess Rt having depth dt. By forming recess Rt, the height of the surface of silicon substrate 31 located between select gate electrodes SG becomes lower than the height of the surface of silicon substrate 31 located between select gate electrode SG and memory gate electrode MG or between memory gate electrodes MG. That is, the surfaces of silicon substrate 31 located on the two sides of select gate electrode SG are processed so that the surface in the select gate electrode SG side is lower than the surface in the memory gate electrode MG side.

Then, an insulating film such as a silicon oxide film is formed in a predetermined thickness by CVD under conditions providing good coverage as illustrated in FIG. 24. Thereafter, the insulating film is etched back by anisotropically etching the entire surface by RIE and spacers 40 are formed along the side surfaces of gate electrodes SG extending from the height of the upper surfaces of gate electrodes SG to the height of the bottom surface of recess Rt located in silicon substrate 31.

Next, impurities such as phosphorous for example are introduced by ion implantation into the surface of source/drain region lowered by recess Rt and located in the portion where select gate electrodes SG face one another. Thus, source/drain region 31c is formed in a region lower than the surface of silicon substrate 31. The impurities in source/drain region 31c spread to the region indicated by a solid line in FIG. 22 by diffusion caused by thermal treatment. In this state, the end portion of recess Rt in source/drain region 31c is spaced from the portion immediately under gate electrode SG by distance dt.

The rest of the process steps are similar to those of the third embodiment and thus, are not described.

By employing the above described manufacturing process steps of the fourth embodiment, it is also possible to provide recess Rt by the over etching performed in the processing of select gate electrode SG. It is thus, possible to form recess Rt easily and inexpensively without having to add dedicated process steps for forming recess Rt.

### Other Embodiments

The foregoing embodiments may be modified as follows.

The first embodiment or the second embodiment may be applied to a flat-cell type configuration.

Other than flat-cell type configuration, the third embodiment or the fourth embodiment may be applied to configurations that arrange the conductive layer, such as polycrystalline silicon film 34, of select gate electrode SG to be placed in a floating state.

The third embodiment and the fourth embodiment may each be applied to the first embodiment or the second embodiment. Further, the third embodiment and the fourth embodiment may be applied to the combination of the first embodiment and the second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a plurality of memory cells arranged in a matrix in a memory cell region of a semiconductor substrate;
a peripheral circuit disposed in a peripheral circuit region outside the memory cell region and configured to read data from and write data to the memory cells; and
a word line transfer transistor provided in the peripheral circuit and having a gate electrode above the semiconductor substrate via a gate insulating film and two impurity diffusion regions provided in two sides of the gate electrode, the word line transfer transistor being configured to supply a voltage to a word line connecting the memory cells;
wherein among the two impurity diffusion regions of the word line transfer transistor, a level of a surface position of the semiconductor substrate in one impurity diffusion region is lower than a level of a surface position of the semiconductor substrate in the other impurity diffusion region.

2. The nonvolatile semiconductor storage device according to claim 1, wherein among the two impurity diffusion regions of the word line transfer transistor, a level of a surface position of the semiconductor substrate in an impurity diffusion region connected to an electrode in the peripheral circuit side is lower than a level of a surface position of the semiconductor substrate in an impurity diffusion region connected to an electrode in the word line side.

3. The nonvolatile semiconductor storage device according to claim 1, wherein among the two impurity diffusion regions of the word line transfer transistor, a level of a surface position of the semiconductor substrate in an impurity diffusion region connected to an electrode in the word line side is lower than a level of a surface position of the semiconductor substrate in an impurity diffusion region connected to an electrode in the peripheral circuit side.

4. The nonvolatile semiconductor storage device according to claim 1, wherein among the two impurity diffusion regions of the word line transfer transistor, levels of surface positions of the semiconductor substrate in both impurity diffusion regions are lower than a level of a surface position of the semiconductor substrate in an impurity diffusion region located in the memory cells.

5. The nonvolatile semiconductor storage device according to claim 1, wherein the word line transfer transistor is provided with a liner film covering the gate electrode.

6. The nonvolatile semiconductor storage device according to claim 5, wherein the liner film comprises a silicon nitride film.

7. The nonvolatile semiconductor storage device according to claim 1, wherein among the two impurity diffusion regions of the word line transfer transistor, a recess is provided in a surface of at least one impurity diffusion region of the semiconductor substrate.

8. The nonvolatile semiconductor storage device according to claim 7, wherein the recess has a sloped surface portion and a planar surface portion.

9. The nonvolatile semiconductor storage device according to claim 8, wherein the sloped surface portion of the recess have an taper angle ranging from 15 degrees to 45 degrees relative to a surface of the semiconductor substrate.

10. The nonvolatile semiconductor storage device according to claim 8, wherein the recess has a depth ranging from 10 nm to 100 nm.

11. A nonvolatile semiconductor storage device comprising:
a plurality of memory cell transistors and select gate transistors arranged in a matrix in a memory cell region of a semiconductor substrate, the select gate transistors having a gate electrode provided with a floating gate electrode isolated by an insulating film, a level of a surface of the semiconductor substrate located in one side of the gate electrode of the select gate transistor in an adjacent other select gate transistor side is lower than a level of a surface of the semiconductor substrate located in the other side of the gate electrode of the select gate transistor in an adjacent memory cell transistor side.

12. The nonvolatile semiconductor storage device according to claim 11, wherein a recess is formed in the surface of the semiconductor substrate located in the other select gate transistor side of the gate electrode of the select gate transistor.

13. The nonvolatile semiconductor storage device according to claim 11, wherein the recess is formed in a surface of the semiconductor substrate located between the select gate transistor and the other select gate transistor.

14. The nonvolatile semiconductor storage device according to claim 11, wherein the recess is formed in a surface of the semiconductor substrate located between a spacer provided along a sidewall of the select gate transistor and a spacer provided along a sidewall of the other select gate transistor.

15. The nonvolatile semiconductor storage device according to claim 11, further comprising a peripheral circuit disposed in a peripheral circuit region and configured to read data from and write data to the memory cells;
a word line transfer transistor provided in the peripheral circuit and having a gate electrode above the semiconductor substrate via a gate insulating film and two impurity diffusion regions provided in two sides of the gate electrode, the word line transfer transistor being configured to supply a voltage to a word line connecting the memory cells
wherein among the two impurity diffusion regions of the word line transfer transistor, a level of a surface position of the semiconductor substrate in one impurity diffusion region is lower than a level of a surface position of the semiconductor substrate in the other impurity diffusion region.

16. A NAND flash memory device comprising:
a plurality of memory cell transistors and select gate transistors arranged in a matrix in a memory cell region of a semiconductor substrate;
a peripheral circuit disposed in a peripheral circuit region outside the memory cell region and configured to read data from and write data to the memory cells; and
a word line transfer transistor provided in the peripheral circuit and including a gate electrode above the semiconductor substrate via a gate insulating film and two impurity diffusion regions provided in two sides of the gate electrode, the word line transfer transistor being configured to supply a voltage to a word line connecting the memory cells;
wherein among the two impurity diffusion regions of the word line transfer transistor, a recess is provided in a surface of at least one impurity diffusion region of the semiconductor substrate, and
wherein the select gate transistors have gate electrode provided with a floating gate electrode isolated by an insulating film, a recess is provided in a surface of the semiconductor substrate located in a side of the select gate transistor in the adjacent other select gate transistor side.
